(19) United States
(12) Patent Application Publication
(10) Pub. No.: US 2023/0139533 A1
(43) Pub. Date: May 4, 2023

(54) OPTICAL SENSOR INCLUDING NANOPHOTONIC MICROLENS ARRAY AND ELECTRONIC DEVICE INCLUDING THE SAME

(71) Applicant: SAMSUNG ELECTRONICS CO., LTD., Suwon-si (KR)

(72) Inventors: Sangeun MUN, Seoul (KR); Sookyoung ROH, Yongin-si (KR); Sungmo AHN, Yongin-si (KR); Seokho YUN, Seoul (KR)

(73) Assignee: SAMSUNG ELECTRONICS CO., LTD., Suwon-si (KR)

(21) Appl. No.: 17/978,725

(22) Filed: Nov. 1, 2022

(30) Foreign Application Priority Data
Nov. 2, 2021 (KR) 10-2021-0149107

(51) Int. Cl. H01L 27/146; G02B 3/00

(52) U.S. Cl. CPC H01L 27/14627; G02B 3/0056; H01L 27/14645; H01L 27/14621; H01L 27/1463; G02B 5/201

(57) ABSTRACT

An optical sensor includes: a sensor substrate including a plurality of pixels that sense incident light, a filter layer arranged on the sensor substrate and including a plurality of filters corresponding to the plurality of pixels, the plurality of filters transmitting only light of a particular wavelength band, and a nanophotonic microlens array arranged on the filter layer and including a plurality of nanophotonic microlenses, each of which focuses incident light on a corresponding pixel among the plurality of pixels.

### CROSS-REFERENCE TO RELATED APPLICATION

This application is based on and claims priority under 35 U.S.C. § 119 to Korean Patent Application No. 10-2021-0149107, filed on Nov. 2, 2021, in the Korean Intellectual Property Office, the disclosure of which is incorporated by reference herein in its entirety.

### BACKGROUND

### 1. Field

Example embodiments of the present disclosure relate to an optical sensor including a nanophotonic microlens array, and an electronic device including the optical sensor.

### 2. Description of Related Art

Optical sensors, such as image sensors or spectroscopic sensors, include a sensor substrate including a plurality of pixels, and an optical lens array provided on the sensor substrate and including a plurality of optical lenses covering the pixels. Each of the plurality of pixels may include a plurality of sub-pixels that are separated from each other by a deep trench isolation (DTI) structure, and an autofocusing (AF) technique may be implemented by calculating differences between output signals of the plurality of sub-pixels based on the DTI structure.

For example, each of the plurality of pixels included in the sensor substrate may include a total of four sub-pixels arranged in a 2×2 configuration, and one optical lens may cover four sub-pixels included in one pixel. In this case, the four sub-pixels arranged in a 2×2 shape may be separated from each other by a cross-shaped DTI structure. In a process of collecting the incident light on the four sub-pixels by using the optical lens to realize the AF technique, a part of incident light may be collected on the center of the pixel. In this case, the incident light collected on the center of the pixel by the optical lens may be absorbed by the DTI structure provided at the center of the pixel, and thus light loss may occur.

In a process of collecting light on the center of the DTI structure and a plurality of sub-pixels separated by the DTI structure to realize the AF technique, it is necessary to design an optical lens array having a structure capable of reducing the amount of incident light collected on the center of the DTI structure so as to minimize light loss.

Moreover, as optical sensors, such as image sensors or spectroscopic sensors, and imaging modules are gradually miniaturized, a chief ray angle (CRA) at an edge of an optical sensor is increasing. As the CRA at the edge of the optical sensor increases, the sensitivity of the pixels located at the edge of the optical sensor decreases. This may cause the edge of an image to be dark. In addition, an additional complicated color calculation for compensating for this may impose a burden on an image processing processor and reduce the image processing speed.

### SUMMARY

One or more example embodiments provide an optical sensor including a nanophotonic microlens array having a structure configured to reduce the amount of incident light collected on the center of a deep trench isolation (DTI) structure included in each of a plurality of pixels of a sensor substrate while implementing an autofocusing (AF) technique, and an electronic device including the optical sensor.

One or more example embodiments also provide an optical sensor including a nanophotonic microlens array configured to change a traveling direction of incident light, which is incident on an edge of the optical sensor at a high CRA to improve the sensitivity of a sensor substrate including a plurality of pixels, and an electronic device including the optical sensor.

Additional aspects will be set forth in part in the description which follows and, in part, will be apparent from the description, or may be learned by practice of example embodiments.

According to an aspect of an example embodiment, there is provided an optical sensor including a sensor substrate including a plurality of pixels configured to sense incident light, a filter layer provided on the sensor substrate and including a plurality of filters respectively corresponding to the plurality of pixels, the plurality of filters being configured to transmit light of a certain wavelength band, and a nanophotonic microlens array provided on the filter layer and including a plurality of nanophotonic microlenses, each of the plurality of nanophotonic microlenses being configured to focus incident light on a corresponding pixel among the plurality of pixels, wherein each of the plurality of pixels includes a deep trench isolation (DTI) and a plurality of photosensitive cells that are electrically separated from each other by the DTI structure and are two-dimensionally provided in a first direction and a second direction perpendicular to the first direction, each of the plurality of photosensitive cells being configured to independently sense light, wherein each of the plurality of nanophotonic microlenses is formed such that light transmitted through each of the nanophotonic microlenses have a phase profile having a plurality of convex regions and to collect incident light on each of a plurality of regions, which are spaced apart from centers of the plurality of photosensitive cells included in the corresponding pixel, toward the DTI structure, and wherein a portion of incident light transmitted through each of the plurality of nanophotonic microlenses is incident on the DTI structure.

Each of the plurality of nanophotonic microlenses may be formed such that a number of convex regions of the phase profile of the light transmitted through each of the plurality of nanophotonic microlenses is equal to a number of photosensitive cells included in the pixel corresponding to each of the plurality of nanophotonic microlenses.

Each of the plurality of nanophotonic microlenses may be formed such that light transmitted through a first region corresponding to the DTI structure of each of the plurality of nanophotonic microlenses has a phase profile of a region in which the plurality of convex regions overlap each other, and light transmitted through a second region that is a remaining region other than the first region in each of the plurality of nanophotonic microlenses has a phase profile having the plurality of convex regions.

Each of the plurality of nanophotonic microlenses may be formed such that the plurality of convex regions of the phase profile of the light transmitted through each of the plurality of nanophotonic microlenses are symmetrically provided with respect to a first area corresponding to the DTI structure of each of the plurality of nanophotonic microlenses.

Each of the plurality of nanophotonic microlenses may be formed such that a phase profile of light transmitted through a third region corresponding to a region between the DTI structure and center points of the plurality of photosensitive cells of each of the plurality of nanophotonic microlenses includes a plurality of maximum points.

Each of a plurality of first nanophotonic microlenses, which is provided in a central region of the nanophotonic microlens array, may be formed such that a plurality of convex regions of a phase profile of light transmitted through each of the plurality of first nanophotonic microlenses are symmetrically provided with respect to a first region corresponding to a DTI structure of each of the plurality of first nanophotonic microlenses, and each of a plurality of second nanophotonic microlenses, which is provided in a peripheral region of the nanophotonic microlens array, may be formed such that a phase profile of light transmitted through each of the plurality of second nanophotonic microlenses has an inclined linear phase profile and a convex phase profile mixed with each other.

The nanophotonic microlens array may include a plurality of third nanophotonic microlenses provided farther from a central region of the nanophotonic microlens array than the plurality of second nanophotonic microlenses, and each of the plurality of second nanophotonic microlenses may be formed such that a first slope of the linear phase profile of the light transmitted through each of the plurality of second nanophotonic microlenses is less than a second slope of the linear phase profile of light transmitted through each of the plurality of third nanophotonic microlenses.

Each of the plurality of nanophotonic microlenses may include a convex lens structure having a plurality of convex portions.

A number of convex portions included in each of the plurality of nanophotonic microlenses may be equal to a number of photosensitive cells included in each pixel corresponding to each of the plurality of nanophotonic microlenses.

A first region corresponding to the DTI structure of each of the plurality of nanophotonic microlenses may be concave, and the plurality of convex portions are included in a second region that is a remaining region other than the first region of each of the plurality of nanophotonic microlenses.

The plurality of convex portions of each of the plurality of nanophotonic microlenses may be symmetrically provided with respect to a first region corresponding to the DTI structure of each of the plurality of nanophotonic microlenses.

Each of the plurality of nanophotonic microlenses may be formed such that maximum points of the plurality of convex portions are provided in a third region corresponding to a region between the DTI structure and center points of the plurality of photosensitive cells of each of the plurality of nanophotonic microlenses.

Each of the plurality of nanophotonic microlenses may include a single convex lens structure in which a plurality of convex lens-shaped portions partially overlap each other with respect to a center point of the nanophotonic microlens, and the number of the plurality of convex lens-shaped portions may correspond to a number of photosensitive cells included in the pixel corresponding to the nanophotonic microlens.

Each of a plurality of first nanophotonic microlenses, which is provided in a central region of the nanophotonic microlens array, may be formed such that a plurality of first convex portions of each of the plurality of first nanophotonic microlenses are symmetrically provided with respect a first region corresponding to the DTI structure of each of the plurality of first nanophotonic microlenses, each of a plurality of 2-1st nanophotonic microlenses, which is provided in a left peripheral region of the nanophotonic microlens array, may be formed such that each of maximum points of a plurality of 2-1st convex portions of each of the plurality of 2-1st nanophotonic microlenses are respectively spaced apart from each of center points of the plurality of photosensitive cells in the first direction, and provided to be closer to a center line of the DTI structure in the first direction than to each of the center points of the plurality of photosensitive cells, and each of a plurality of 2-2nd nanophotonic microlenses, which is provided in a right peripheral region of the nanophotonic microlens array, may be formed such that each of maximum points of a plurality of 2-2nd convex portions of each of the plurality of 2-2nd nanophotonic microlenses are respectively spaced apart from each of the center points of the plurality of photosensitive cells in a direction opposite to the first direction, and are provided to be closer to the center line of the DTI structure in the first direction than to each of the center points of the plurality of photosensitive cells.

The plurality of 2-1st convex portions of each of the plurality of 2-1st nanophotonic microlenses and the plurality of 2-2nd convex portions of each of the plurality of 2-2nd nanophotonic microlenses may be symmetrically provided in the second direction with respect to the center line of the DTI structure in the first direction.

The nanophotonic microlens array may include a plurality of third nanophotonic microlenses provided farther from a central region of an array of the nanophotonic microlenses than the plurality of 2-1st nanophotonic microlenses and the plurality of 2-2nd nanophotonic microlenses, and a distance by which a plurality of maximum points of a plurality of third convex portions of each of the plurality of third nanophotonic microlenses may be spaced apart from the center points of the plurality of photosensitive cells is greater than a distance by which a plurality of maximum points of a plurality of second convex portions of each of the plurality of 2-1st nanophotonic microlenses and the plurality of 2-2nd nanophotonic microlenses are spaced apart from the plurality of center points of the plurality of photosensitive cells.

The plurality of pixels may include a plurality of first pixels each including a plurality of first photosensitive cells configured to sense light of a first wavelength band and a plurality of second pixels each including a plurality of second photosensitive cells configured to sense light of a second wavelength band that is shorter than the first wavelength band, the filter layer may include a plurality of first filters respectively corresponding to the plurality of first pixels and configured to transmit light of the first wavelength band, and a plurality of second filters respectively corresponding to the plurality of second pixels and configured to transmit light of the second wavelength band, and the nanophotonic microlens array may include a plurality of first nanophotonic microlenses corresponding to the plurality of first filters, respectively, and configured to focus light on the plurality of first pixels, and a plurality of second nanophotonic microlenses corresponding to the plurality of second filters, respectively, and configured to focus light on the plurality of second pixels.

The plurality of first nanophotonic microlenses and the plurality of second nanophotonic microlenses may be formed such that a plurality of second convex regions included in a phase profile of light transmitted through each of the plurality of second nanophotonic microlenses are more convex than a plurality of first convex regions included in a phase profile of light transmitted through each of the plurality of first nanophotonic microlenses.

Each of the plurality of first nanophotonic microlenses may include a first convex lens structure having a plurality of first convex portions, each of the plurality of second nanophotonic microlenses may include a second convex lens structure having a plurality of second convex portions, and the plurality of second convex portions may be formed to be more convex than the plurality of first convex portions.

A number of first convex portions included in each of the plurality of first nanophotonic microlenses may be equal to a number of first photosensitive cells included in each of the plurality of first pixels, and a number of second convex portions included in each of the plurality of second nanophotonic microlenses may be equal to a number of second photosensitive cells included in each of the plurality of second pixels.

Each of the plurality of first nanophotonic microlenses may be formed such that the plurality of first convex portions included in the first nanophotonic microlens are symmetrically provided with respect a first region corresponding to the DTI structure of the first nanophotonic microlens, and each of the plurality of second nanophotonic microlenses may be formed such that the plurality of second convex portions included in the second nanophotonic microlens are symmetrically provided with respect a second region corresponding to the DTI structure of the second nanophotonic microlens.

Each of the plurality of first nanophotonic microlenses and each of the plurality of second nanophotonic microlenses provided in a central region of the nanophotonic microlens array may be formed such that the plurality of first convex portions of each of the plurality of first nanophotonic microlenses are symmetrically provided with respect to a first region corresponding to the DTI structure of each of the plurality of first nanophotonic microlenses, and the plurality of second convex portions of each of the plurality of second nanophotonic microlenses may be symmetrically provided with respect to a second region corresponding to the DTI structure of each of the plurality of second nanophotonic microlenses, each of the plurality of first nanophotonic microlenses and each of the plurality of second nanophotonic microlenses provided in a left peripheral region of the nanophotonic microlens array may be formed such that maximum points of the plurality of first convex portions of each of the plurality of first nanophotonic microlenses and maximum points of the plurality of second convex portions of each of the plurality of second nanophotonic microlenses are respectively spaced apart from each of center points of the plurality of first photosensitive cells included in each of the plurality of first pixels and each of center points of the plurality of second photosensitive cells included in each of the plurality of second pixels in the first direction, and may be provided to be closer to a center line of the DTI structure in the first direction than to each of center points of the plurality of first photosensitive cells and each of center points of the plurality of second photosensitive cells, and each of the plurality of first nanophotonic microlenses and each of the plurality of second nanophotonic microlenses provided in a right peripheral region of the nanophotonic microlens array may be formed such that maximum points of the plurality of first convex portions of each of the plurality of first nanophotonic microlenses and maximum points of the plurality of second convex portions of each of the plurality of second nanophotonic microlenses are respectively spaced apart from each of center points of the plurality of first photosensitive cells included in each of the plurality of first pixels and each of center points of the plurality of second photosensitive cells included in each of the plurality of second pixels in a direction opposite to the first direction, and may be provided to be closer to a center line of the DTI structure in the first direction than to each of center points of the plurality of first photosensitive cells and each of center points of the plurality of second photosensitive cells.

The plurality of first convex portions of each of the plurality of first nanophotonic microlenses provided in the left peripheral region and the right peripheral region of the nanophotonic microlens array and the plurality of second convex portions of each of the plurality of second nanophotonic microlenses provided in the left peripheral region and the right peripheral region of the nanophotonic microlens array may be symmetrically provided in the second direction with respect to a center line of the DTI structure.

Each of the plurality of nanophotonic microlenses may include a plurality of nanostructures provided such that light transmitted through each of the plurality of nanophotonic microlenses has a phase profile having a plurality of convex regions.

Each of the plurality of nanophotonic microlenses may include a sparse area including a plurality of first nanostructures, and a dense area including a plurality of second nanostructure, the dense area may be provided adjacent to the sparse area, and diameters of the plurality of first nanostructures may be less than diameters of the plurality of second nanostructures.

The dense area included in each of the plurality of nanophotonic microlenses may include a plurality of sub-dense areas spaced apart from each other by the sparse area.

A number of sub-dense areas included in each of the plurality of nanophotonic microlenses may be equal to a number of photosensitive cells included in each pixel corresponding to each of the plurality of nanophotonic microlenses.

The sparse area may correspond to a center region and an edge region of each of the plurality of nanophotonic microlenses, and the plurality of sub-dense areas may be symmetrically provided with respect to a region corresponding to the DTI structure of each of the plurality of nanophotonic microlenses.

Each of the plurality of nanophotonic microlenses may be formed such that center points of the plurality of sub-dense areas are provided in a region corresponding to a region between the DTI structure and center points of the plurality of photosensitive cells of each of the plurality of nanophotonic microlenses.

The plurality of first nanophotonic microlenses provided in a central region of the nanophotonic microlens array may be formed such that a first sparse area of each of the plurality of first nanophotonic microlenses corresponds to a center and an edge region of each of the plurality of first nanophotonic microlenses, and a plurality of first sub-dense areas of each of the plurality of first nanophotonic microlenses may be symmetrically provided with respect to a region corresponding to the DTI structure of each the plurality of first nanophotonic microlenses, each of a plurality of 2-1st nanophotonic microlenses provided in a left peripheral region of the nanophotonic microlens array may be formed such that center points of each of a plurality of 2-1st sub-dense areas of each of the plurality of 2-1st nanophotonic microlenses are respectively spaced apart from the each of center points of the plurality of photosensitive cells in the first direction, and may be provided to be closer to a center line of the DTI structure in the first direction than to each of the center points of the plurality of photosensitive cells, and each of a plurality of 2-2nd nanophotonic microlenses provided in a right peripheral region of the nanophotonic microlens array may be formed such that center points of each of a plurality of 2-2nd sub-dense areas of each of the plurality of 2-2nd nanophotonic microlenses are respectively spaced apart from the each of center points of the plurality of photosensitive cells in a direction opposite to the first direction, and may be provided to be closer to the center line of the DTI structure in the first direction than to each of the center points of the plurality of photosensitive cells.

The plurality of 2-1st sub-dense areas of each of the plurality of 2-1st nanophotonic microlenses and a plurality of 2-2nd sub-dense areas of each of the plurality of 2-2nd nanophotonic microlenses may be symmetrically provided in the second direction with respect to the center line of the DTI structure in the first direction.

The nanophotonic microlens array may include a plurality of third nanophotonic microlenses provided farther from a central region of an array of the nanophotonic microlenses than the plurality of 2-1st nanophotonic microlenses and the plurality of 2-2nd nanophotonic microlenses, and a distance by which a plurality of center points of a plurality of third sub-dense areas of each of the plurality of third nanophotonic microlenses are spaced apart from the plurality of center points of the plurality of photosensitive cells may be greater than a distance by which a plurality of center points of a plurality of 2-1st sub-dense areas and a plurality of 2-2nd sub-dense areas of each of the plurality of 2-1st nanophotonic microlenses and the plurality of 2-2nd nanophotonic microlenses are spaced apart from the plurality of center points of the plurality of photosensitive cells.

The plurality of pixels may include a plurality of first pixels each including a plurality of first photosensitive cells configured to sense light of a first wavelength band and a plurality of second pixels each including a plurality of second photosensitive cells configured to sense light of a second wavelength band that is shorter than the first wavelength band, the filter layer may include a plurality of first filters corresponding to the plurality of first pixels and configured to transmit light of the first wavelength band, and a plurality of second filters corresponding to the plurality of second pixels and configured to transmit light of the second wavelength band, and the nanophotonic microlens array may include a plurality of first nanophotonic microlenses corresponding to the plurality of first filters, respectively, and may be configured to focus light on the plurality of first pixels, and a plurality of second nanophotonic microlenses corresponding to the plurality of second filters, respectively, and configured to focus light on the plurality of second pixels.

An average diameter of a plurality of first nanostructures included in the dense area of each of the plurality of first nanophotonic microlenses may be less than an average diameter of a plurality of second nanostructures included in the dense area of each of the plurality of second nanophotonic microlenses.

Each of the plurality of first nanophotonic microlenses and each of the plurality of second nanophotonic microlenses provided in a central region of the nanophotonic microlens array may be formed such that a plurality of first sub-dense areas of each of the plurality of first nanophotonic microlenses are symmetrically provided with respect to a first region corresponding to the DTI structure of each of the plurality of first nanophotonic microlenses, and a plurality of second sub-dense areas of each of the plurality of second nanophotonic microlenses are symmetrically provided with respect to a second region corresponding to the DTI structure of each of the plurality of second nanophotonic microlenses, each of the plurality of first nanophotonic microlenses and each of the plurality of second nanophotonic microlenses provided in a left peripheral region of the nanophotonic microlens array may be formed such that center points of each of the plurality of first sub-dense areas of each of the plurality of first nanophotonic microlenses and center points of each of the plurality of second sub-dense areas of each of the plurality of second nanophotonic microlenses are respectively spaced apart from each of the center points of the plurality of photosensitive cells in the first direction, and are provided to be closer to a center line of the DTI structure in the first direction than to each of the center points of the plurality of photosensitive cells, and each of the plurality of first nanophotonic microlenses and each of the plurality of second nanophotonic microlenses provided in a right peripheral region of the nanophotonic microlens array may be formed such that center points of each of the plurality of first sub-dense areas of each of the plurality of first nanophotonic microlenses and center points of each of the plurality of second sub-dense areas of each of the plurality of second nanophotonic microlenses are respectively spaced apart from each of the center points of the plurality of photosensitive cells in a direction opposite to the first direction, and may be provided to be closer to a center line of the DTI structure in the first direction than to each of the center points of the plurality of photosensitive cells.

According to another aspect of an example embodiment, there is provided an electronic device including an optical sensor configured to convert an optical image into an electrical signal, and a processor configured to control an operation of the optical sensor, and store and output a signal generated by the optical sensor, wherein the optical sensor may include a sensor substrate including a plurality of pixels configured to sense incident light, a filter layer provided on the sensor substrate and including a plurality of filters respectively corresponding to the plurality of pixels, the plurality of filters being configured to transmit light of a certain wavelength band, and a nanophotonic microlens array provided on the filter layer and including a plurality of nanophotonic microlenses, each of the plurality of nanophotonic microlenses being configured to focus incident light on a corresponding pixel among the plurality of pixels, wherein each of the plurality of pixels includes a deep trench isolation (DTI) and a plurality of photosensitive cells that are electrically separated from each other by the DTI structure, and are two-dimensionally provided in a first direction and a second direction perpendicular to the first direction, each of the plurality of photosensitive cells being configured to independently sense light, wherein each of the plurality of nanophotonic microlenses is formed such that light transmitted through each of the nanophotonic microlenses have a phase profile having a plurality of convex regions and to collect incident light on each of a plurality of regions, which are spaced apart from centers of the plurality of photosensitive cells included in the corresponding pixel, toward the DTI structure, and wherein a portion of incident light transmitted through each of the plurality of nanophotonic microlenses is incident on the DTI structure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an optical sensor according to an example embodiment;

FIGS. 2, 3, and 4 are diagrams illustrating examples of a pixel arrangement of a pixel array of an optical sensor;

FIG. 5 is a conceptual diagram schematically illustrating a camera module according to an example embodiment;

FIG. 6 is a plan view of a pixel array of an optical sensor according to an example embodiment;

FIG. 7 is a perspective view illustrating an example configuration of a pixel array included in an optical sensor according to an example embodiment;

FIG. 8 is a plan view illustrating an example configuration of the pixel array of FIG. 7;

FIG. 9 is a plan view illustrating an example configuration of a sensor substrate included in the pixel array of FIG. 7;

FIG. 10 is a cross-sectional view taken along line A-A′ of the pixel array of FIG. 7;

FIG. 11 is a cross-sectional view taken along line B-B′ of the pixel array of FIG. 7;

FIG. 12 is a diagram illustrating a phase profile of light transmitted through a portion along line A-A′ of the pixel array of FIG. 7;

FIG. 13 is a diagram illustrating a phase profile of light transmitted through a portion along line B-B′ of the pixel array of FIG. 7;

FIG. 14 is a diagram illustrating a phase profile of light transmitted through a portion along line C-C′ of the pixel array of FIG. 7;

FIG. 15 is a diagram illustrating a phase profile of light transmitted through a portion along line D-D′ of the pixel array of FIG. 7;

FIG. 16 is a plan view illustrating an example configuration of a peripheral portion of a pixel array included in an optical sensor according to another example embodiment;

FIG. 17 is a cross-sectional view taken along line E-E′ in the peripheral portion of the pixel array of FIG. 16;

FIG. 18 is a cross-sectional view taken along line F-F′ in the peripheral portion of the pixel array of FIG. 16;

FIG. 19 is a diagram illustrating a phase profile of light transmitted through a portion along line E-E′ in the peripheral portion of the pixel array of FIG. 16;

FIG. 20 is a plan view illustrating an example configuration of a pixel array included in an optical sensor, according to another example embodiment;

FIG. 21 is a cross-sectional view taken along line G-G′ of the pixel array of FIG. 20;

FIG. 22 is a cross-sectional view taken along line H-H′ of the pixel array of FIG. 20;

FIG. 23 is a diagram illustrating a phase profile of light transmitted through a portion along line G-G′ of the pixel array of FIG. 7;

FIG. 24 is a diagram illustrating a phase profile of light transmitted through a portion along line H-H′ of the pixel array of FIG. 7;

FIG. 25 is a plan view illustrating an example configuration of a pixel array included in an optical sensor according to another example embodiment;

FIG. 26 is a cross-sectional view taken along line I-I′ of the pixel array of FIG. 25;

FIG. 27 is a cross-sectional view taken along line J-J′ of the pixel array of FIG. 25;

FIG. 28 is a cross-sectional view taken along line K-K′ of the pixel array of FIG. 25;

FIG. 29 is a cross-sectional view taken along line L-L′ of the pixel array of FIG. 25;

FIG. 30 is a diagram illustrating a phase profile of light transmitted through a portion along line I-I′ of the pixel array of FIG. 25;

FIG. 31 is a diagram illustrating a phase profile of light transmitted through a portion along line J-J′ of the pixel array of FIG. 25;

FIG. 32 is a diagram illustrating a phase profile of light transmitted through a portion along line K-K′ of the pixel array of FIG. 25;

FIG. 33 is a diagram illustrating a phase profile of light transmitted through a portion along line L-L′ of the pixel array of FIG. 25;

FIG. 34 is a perspective view illustrating an example configuration of a pixel array included in an optical sensor according to another example embodiment;

FIG. 35 is a plan view illustrating an example configuration of the pixel array of FIG. 34;

FIG. 36 is a plan view illustrating an example configuration of a first nanophotonic microlens included in the pixel array of FIG. 34;

FIG. 37 is a plan view illustrating an example configuration of a pixel array included in an optical sensor according to another example embodiment;

FIG. 38 is a plan view illustrating an example configuration of a first nanophotonic microlens included in the pixel array of FIG. 34;

FIG. 39 is a plan view illustrating an example configuration of a pixel array included in an optical sensor according to another example embodiment;

FIG. 40 is a plan view illustrating an example configuration of a pixel array included in an optical sensor according to another example embodiment;

FIG. 41 is a block diagram illustrating an electronic device including an image sensor according to an example embodiment;

FIG. 42 is a block diagram illustrating the camera module illustrated in FIG. 41; and

FIGS. 43, 44, 45, 46, 47, 48, 49, 50, 51, and 52 are diagrams illustrating various examples of electronic devices including optical sensors according to various example embodiments.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects.

As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

In the drawings, the size or thickness of each element may be exaggerated for clarity and convenience of description.

Terms such as “first” or “second” may be used to describe various elements, but the elements should not be limited by the terms. These terms are only used to distinguish one element from another element.

Throughout the specification, when a part “includes” an element, it is to be understood that the part may additionally include other elements rather than excluding other elements as long as there is no particular opposing recitation.

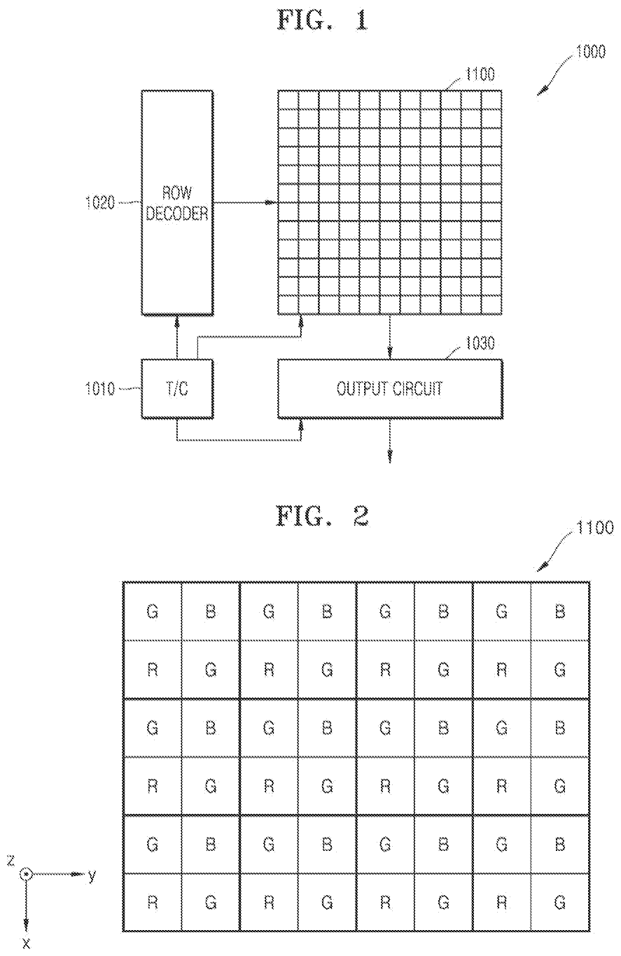

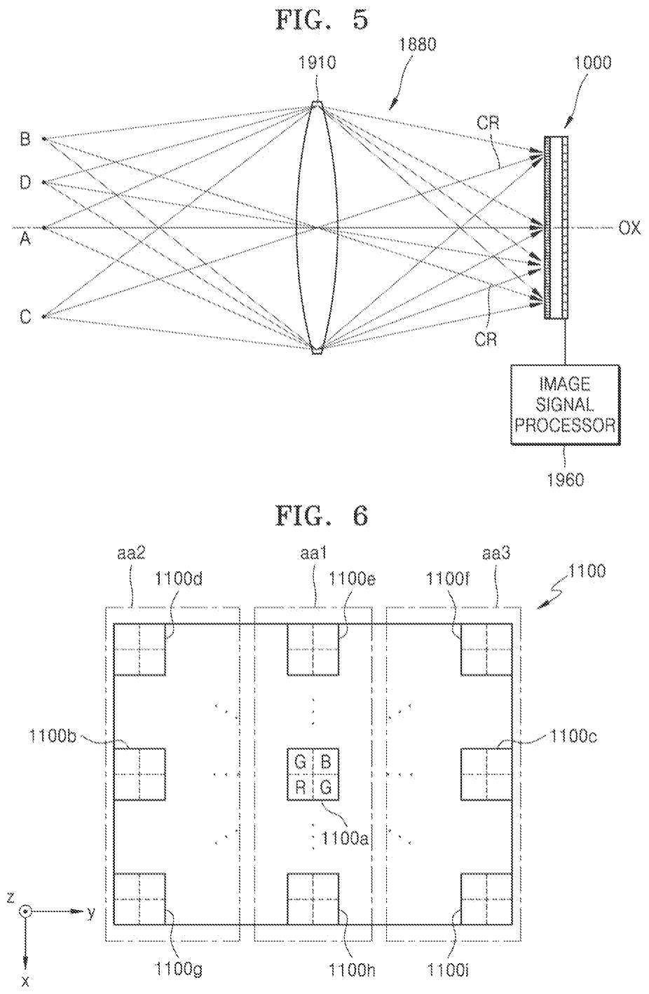

FIG. 1 is a block diagram of an optical sensor 1000 according to an example embodiment. FIGS. 2 to 4 are diagrams illustrating examples of a pixel arrangement of a pixel array 1100 of the optical sensor 1000. FIG. 5 is a conceptual diagram illustrating a camera module 1880 according to an example embodiment. FIG. 6 is a plan view of the pixel array 1100 of the optical sensor 1000, according to an example embodiment.

Referring to FIG. 1, the optical sensor 1000 may include the pixel array 1100, a timing controller 1010, a row decoder 1020, and an output circuit 1030. The optical sensor 1000 may be, for example, a charge-coupled device (CCD) image sensor or a complementary metal-oxide-semiconductor (CMOS) image sensor.

The pixel array 1100 includes a plurality of pixels that are two-dimensionally arranged along a plurality of rows and columns. The row decoder 1020 selects one of the rows of the pixel array 1100 in response to a row address signal output from the timing controller 1010. The output circuit 1030 outputs, from the plurality of pixels arranged along the selected row, a light sensing signal in column units. To this end, the output circuit 1030 may include a column decoder and an analog-to-digital converter (ADC). For example, the output circuit 1030 may include a plurality of ADCs arranged for each column between the column decoder and the pixel array 1100 or one ADC arranged at an output terminal of the column decoder. The timing controller 1010, the row decoder 1020, and the output circuit 1030 may be implemented as a single chip or separate chips. A processor for processing an image signal output from the output circuit 1030 may be implemented as a single chip together with the timing controller 1010, the row decoder 1020, and the output circuit 1030.

The pixel array 1100 may include a plurality of pixels that sense light of different wavelength bands. The plurality of pixels may be arranged in various manners. Various examples of a pixel arrangement of the pixel array 1100 of the optical sensor 1000 are illustrated in FIGS. 2 to 4.

First, FIG. 2 shows a Bayer pattern that is used in general image sensors. Referring to FIG. 2, one unit pattern includes four quadrant regions, i.e., first to fourth quadrants, which may be a blue pixel B, a green pixel G, a red pixel R, and a green pixel G, respectively. The unit patterns are repeatedly arranged two-dimensionally in a first direction (y-direction) and a second direction (x-direction). In other words, two green pixels G are arranged in one diagonal direction in a 2×2 array-type unit pattern, and one blue pixel B and one red pixel R are arranged in the other diagonal direction. In the whole pixel arrangement, a first row in which a plurality of green pixels G and a plurality of blue pixels B are alternately arranged in the first direction (y-direction), and a second row in which a plurality of red pixels R and a plurality of green pixels G are alternately arranged in the first direction (y-direction) are repeatedly arranged in the second direction (x-direction).

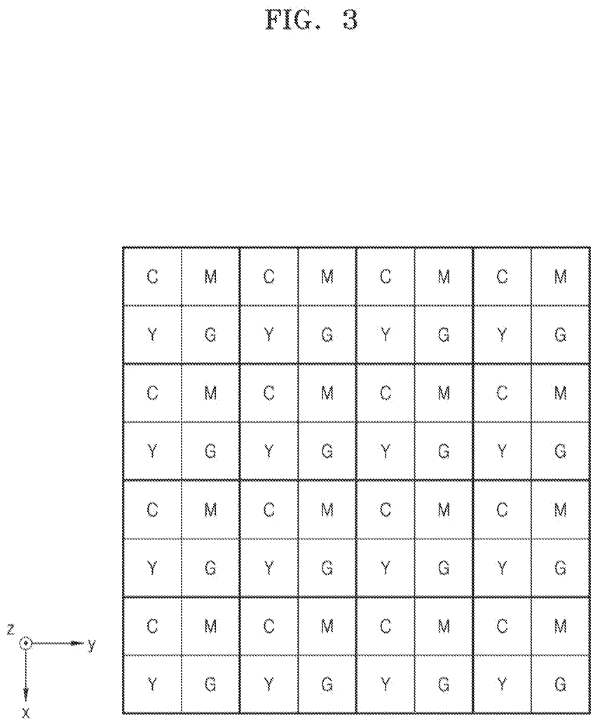

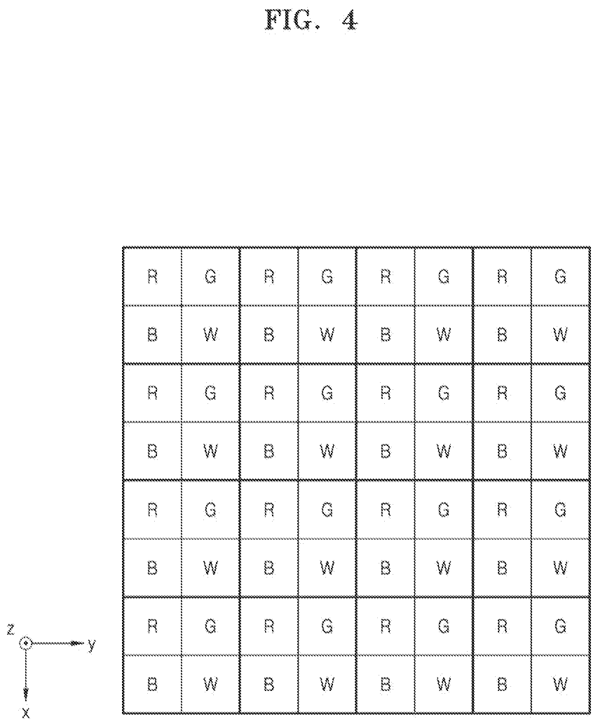

The pixel array 1100 may be arranged in various manners other than the Bayer pattern. For example, referring to FIG. 3, the pixel array 1100 may also be arranged in a CYGM pattern in which a magenta pixel M, a cyan pixel C, a yellow pixel Y, and a green pixel G constitute one unit pattern. In addition, referring to FIG. 4, the pixel array 1100 may also be arranged in an RGBW pattern in which a green pixel G, a red pixel R, a blue pixel B, and a white pixel W constitute one unit pattern. The unit pattern may have a 3×2 array configuration. In addition, the plurality of pixels of the pixel array 1100 may be arranged in various manners according to the use and characteristics of the optical sensor 1000. Hereinafter, it is described that the pixel array 1100 of the optical sensor 1000 has a Bayer pattern, however, the principles of embodiments described below may also be applied to a pixel arrangement other than the Bayer pattern.

The optical sensor 1000 may be applied to various optical devices. For example, referring to FIG. 5, the camera module 1880 according to an example embodiment may include a lens assembly 1910 that focuses light reflected from an object to form an optical image, an optical sensor 1000 that converts the optical image formed by the lens assembly 1910 into an electrical image signal, and an image signal processor 1960 that processes an electrical signal output from the optical sensor 1000 into an image signal. The camera module 1880 may further include an infrared cut-off filter arranged between the optical sensor 1000 and the lens assembly 1910, a display panel for displaying an image formed by the image signal processor 1960, and a memory for storing image data formed by the image signal processor 1960. The camera module 1880 may be mounted in mobile electronic devices such as cellular phones, notebook computers, or tablet personal computers (PCs).

The lens assembly 1910 focuses an image of an object located outside the camera module 1880, on the optical sensor 1000, more specifically, on the pixel array 1100 of the optical sensor 1000. Although FIG. 5 illustrates that the lens assembly 1910 includes one lens for convenience of description, the lens assembly 1910 may include a plurality of lenses. When the pixel array 1100 is accurately located on a focal plane of the lens assembly 1910, light starting from any one point of the object passes through the lens assembly 1910 and is then collected at one point on the pixel array 1100. For example, light starting from a point A on an optical axis OX passes through the lens assembly 1910 and is then collected at the center of the pixel array 1100 on the optical axis OX. Light starting from a point B, C, or D, which deviates from the optical axis OX, travels across the optical axis OX by the lens assembly 1910 and is then collected at one point of a peripheral portion of the pixel array 1100. For example, in FIG. 5, light starting from the point B above the optical axis OX is collected at the lower edge of the pixel array 1100 across the optical axis OX, and light starting from the point C below the optical axis OX is collected at the upper edge of the pixel array 1100 across the optical axis OX. In addition, light starting from the point D between the optical axis OX and the point B is collected at a point between the center and the lower edge of the pixel array 1100.

Therefore, the light starting from the different points A, B, C, and D is incident on the pixel array 1100 at different angles according to the distances between the respective points A, B, C, and D and the optical axis OX. An angle of incidence of light on the pixel array 1100 is generally referred to as a chief ray angle (CRA). A chief ray CR refers to a ray incident on the pixel array 1100 from one point of the object through the center of the lens assembly 1910, and a CRA refers to the angle between the chief ray and the optical axis OX. The light starting from the point A on the optical axis OX has a CRA of 0° and is perpendicularly incident on the pixel array 1100. As the light emission point moves farther away from the optical axis OX, the CRA may increase.

From the viewpoint of the optical sensor 1000, the CRA of the light incident on the center of the pixel array 1100 is 0°, and the CRA of incident light increases toward an edge of the pixel array 1100. For example, the CRA of the light starting from the points B and C and incident on the outermost edges of the pixel array 1100 is greatest, and the CRA of the light starting from the point A and incident on the center of the pixel array 1100 is 0°. In addition, the CRA of the light starting from the point D and incident on the point between the center and the edge of the pixel array 1100 is less than the CRA of the light starting from the points B and C and greater than 0°.

Accordingly, the CRAs of light incident on the plurality of pixels in the pixel array 1100 depend on the positions of the respective pixels. For example, referring to FIG. 6, in a center 1100a included in a central region aa1 of the pixel array 1100, the CRA is 0° in both the first direction (y-direction) and the second direction (x-direction). In addition, as the distance from the center 1100a increases in the first direction (y-direction), the CRA in the first direction (y-direction) gradually increases, and the CRA in the first direction (y-direction) is greatest at left and right central edge portions 1100b and 1100c (i.e., the central edge portions in the first direction (y-direction)) included respectively in peripheral regions aa2 and aa3 of the pixel array 1100. Also, as the distance from the center 1100a increases in the second direction (x-direction), the CRA in the second direction (x-direction) gradually increases, and the CRA in the second direction (x-direction) is greatest at upper and lower edge portions 1100e and 1100h (i.e., the edge portions in the second direction (x-direction)) included in the central region aa1. In addition, as the distance from the center 1100a increases in a diagonal direction, both the CRA in the first direction (y-direction) and the CRA in the second direction (x-direction) gradually increase, and the CRAs in the diagonal directions of the first direction (y-direction) and the second direction (x-direction) are greatest at vertex portions 1100d, 1100f, 1100g, and 1100i are the largest. As the CRA of light incident on the plurality of pixels increases, the sensitivity of the pixels may decrease.

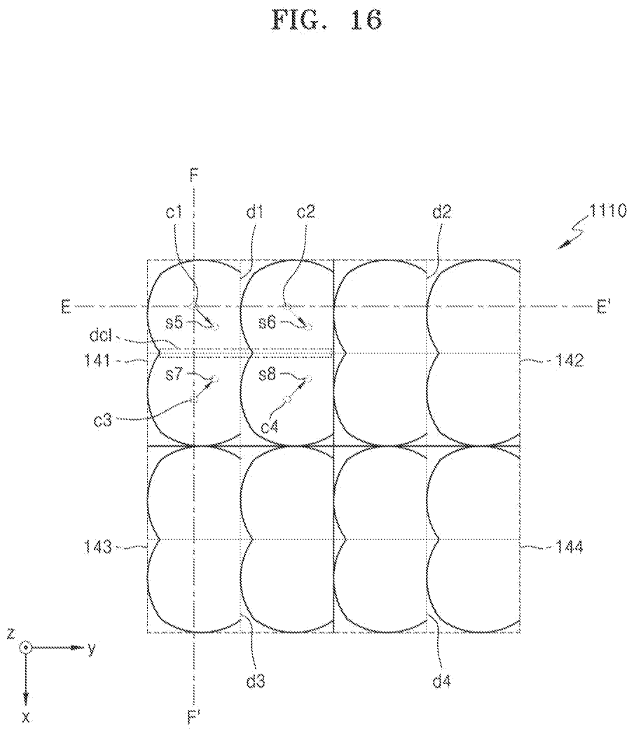

According to various example embodiments, in order to minimize the decrease in sensitivity of the pixels in the peripheral regions aa2 and aa3 of the pixel array 1100, a specially designed nanophotonic microlens array may be arranged in the peripheral regions aa2 and aa3 of the pixel array 1100 of the optical sensor 1000, as described below with reference to FIGS. 16 to 19.

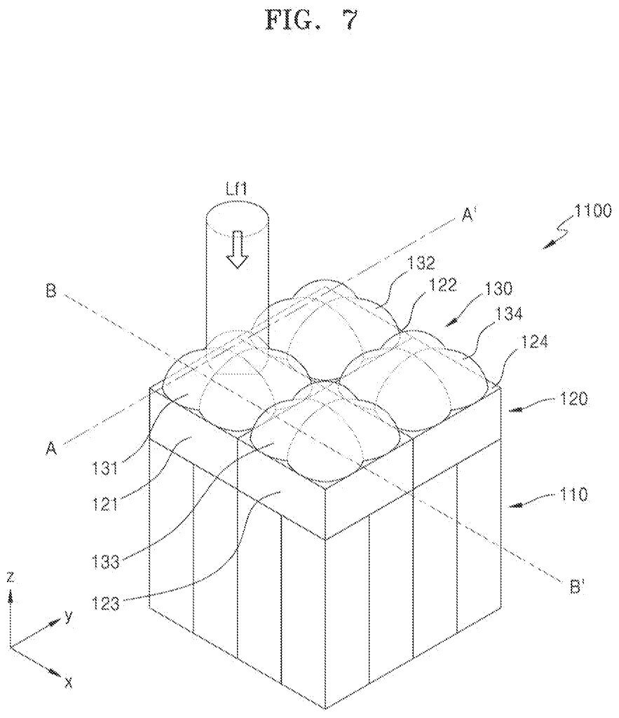

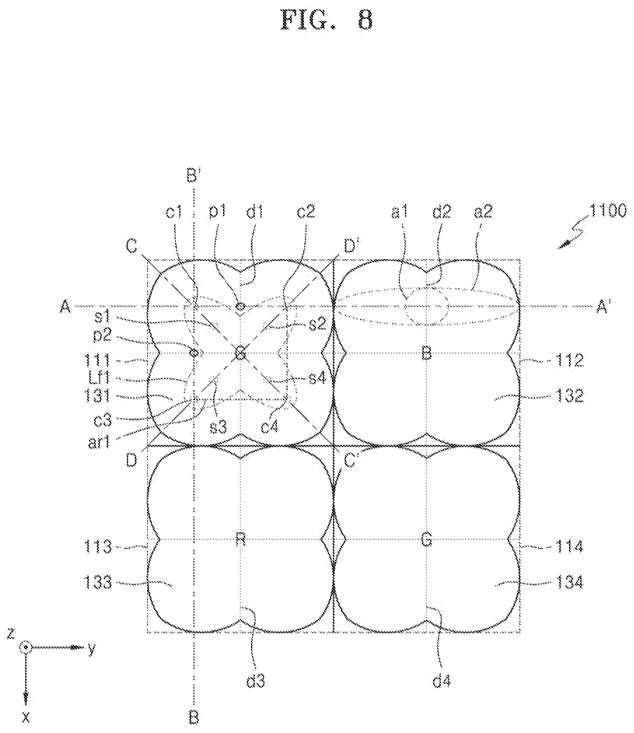

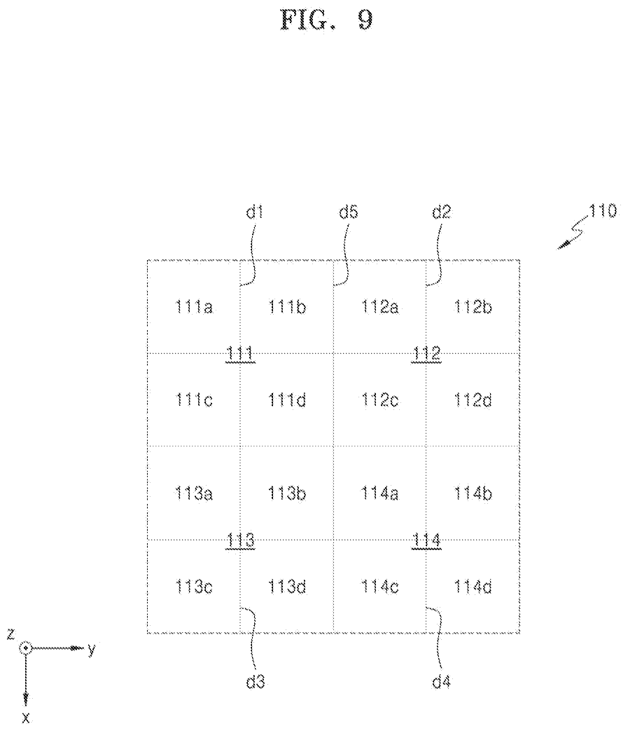

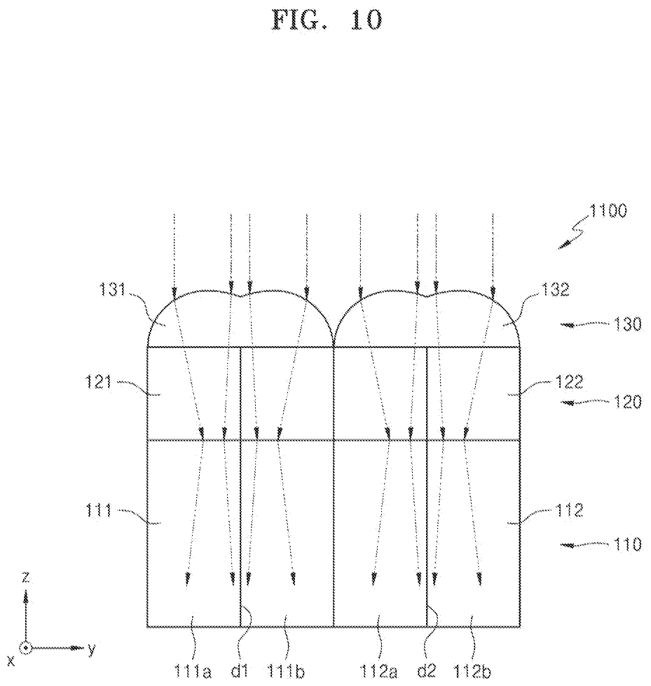

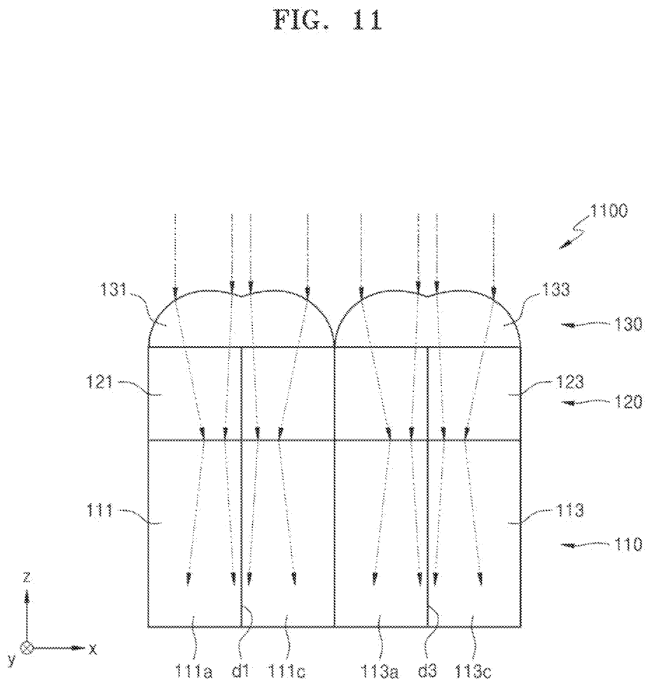

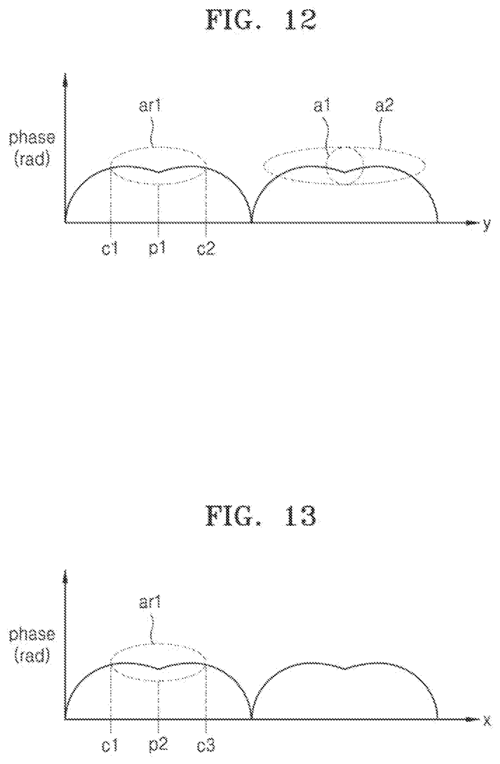

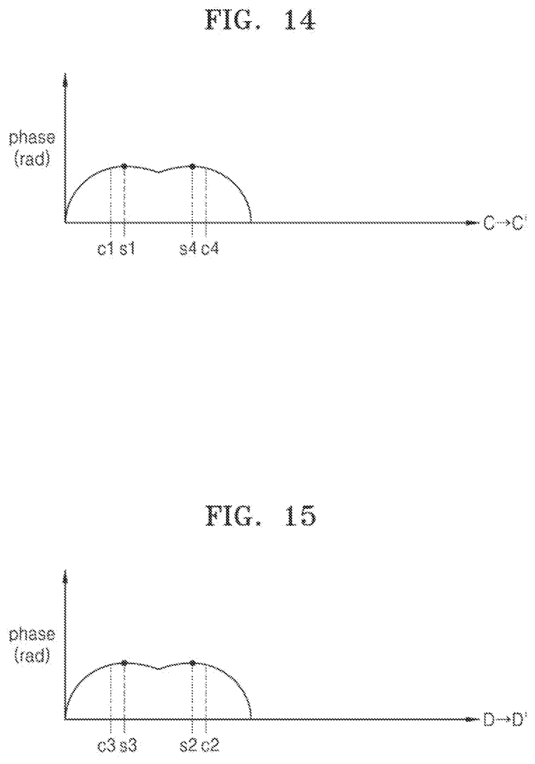

FIG. 7 is a perspective view illustrating an example configuration of the pixel array 1100 included in the optical sensor 1000, according to an example embodiment. FIG. 8 is a plan view illustrating an example configuration of the pixel array 1100 of FIG. 7. FIG. 9 is a plan view illustrating an example configuration of a sensor substrate 110 included in the pixel array 1100 of FIG. 7. FIG. 10 is a cross-sectional view taken along line A-A′ of the pixel array 1100 of FIG. 7. FIG. 11 is a cross-sectional view taken along line B-B′ of the pixel array 1100 of FIG. 7. FIG. 12 is a diagram illustrating a phase profile of light transmitted through a portion along line A-A′ of the pixel array 1100 of FIG. 7. FIG. 13 is a diagram illustrating a phase profile of light transmitted through a portion along line B-B′ of the pixel array 1100 of FIG. 7. FIG. 14 is a diagram illustrating a phase profile of light transmitted through a portion along line C-C′ of the pixel array 1100 of FIG. 8. FIG. 15 is a diagram illustrating a phase profile of light transmitted through a portion along line D-D′ of the pixel array 1100 of FIG. 8.

Referring to FIGS. 7 through 9, the pixel array 1100 may include the sensor substrate 110, a filter layer 120, and a nanophotonic microlens array 130. The filter layer 120 may be provided on the sensor substrate 110, and the nanophotonic microlens array 130 may be provided on the filter layer 120.

The sensor substrate 110 may include a plurality of pixels 111, 112, 113, and 114 (hereinafter, also referred to as a first pixel 111, a second pixel 112, a third pixel 113, and a fourth pixel 114) that sense incident light Lf1. For example, the sensor substrate 110 may include the first pixel 111 and the fourth pixel 114 that sense light of a first wavelength band that is a green light region, the second pixel 112 that senses light of a second wavelength band that is a blue light region, and the third pixel 113 that senses light of a third wavelength band that is a red light region. The sensor substrate 110 may include a unit pattern in which the first pixel 111, the second pixel 112, the third pixel 113, and the fourth pixel 114 are two-dimensionally arranged in the first direction (y-direction) and the second direction (x-direction), which is perpendicular to the first direction (y-direction). A plurality of unit patterns each including the first to fourth pixels 111, 112, 113, and 114 may be two-dimensionally arranged in the first direction (y-direction) and the second direction (x-direction). This arrangement is for sensing the incident light Lf1 in a unit pattern such as a Bayer pattern.

The plurality of pixels 111, 112, 113, and 114 may include deep trench isolation (DTI) structures d1, d2, d3, and d4 (hereinafter, also referred to as a first DTI d1, a second DTI d2, a third DTI d3, and a fourth DTI d4), and a plurality of photosensitive cells 111a, 111b, 111c, 111d, 112a, 112b, 112c, 112d, 113a, 113b, 113c, 113d, 114a, 114b, 114c, and 114d (hereinafter, also referred to as a plurality of first photosensitive cells 111a, 111b, 111c, and 111d, a plurality of second photosensitive cells 112a, 112b, 112c, and 112d, a plurality of third photosensitive cells 113a, 113b, 113c, and 113d, and a plurality of fourth photosensitive cells 114a, 114b, 114c, and 114d) that are electrically separated from each other by the DTI structures d1, d2, d3, and d4 to independently sense light, respectively. Each of the plurality of photosensitive cells 111a, 111b, 111c, 111d, 112a, 112b, 112c, 112d, 113a, 113b, 113c, 113d, 114a, 114b, 114c, and 114d may include one photodiode.

For example, the first pixel 111 may include the plurality of first photosensitive cells 111a, 111b, 111c, and 111d that are two-dimensionally arranged in the first direction (y-direction) and the second direction (x-direction). Referring to FIG. 9, the plurality of first photosensitive cells 111a, 111b, 111c, and 111d may be electrically separated from each other by the first DTI structure d1. The first DTI structure d1 may have a cross shape, and the plurality of first photosensitive cells 111a, 111b, 111c, and 111d may be provided respectively in a second quadrant, a first quadrant, a third quadrant, and a fourth quadrant, which are formed by the first DTI structure d1.

The second pixel 112 may include the plurality of second photosensitive cells 112a, 112b, 112c, and 112d that are two-dimensionally arranged in the first direction (y-direction) and the second direction (x-direction). Referring to FIG. 9, the plurality of second photosensitive cells 112a, 112b, 112c, and 112d may be electrically separated from each other by the second DTI structure d2. The second DTI structure d2 may have a cross shape, and the plurality of second photosensitive cells 112a, 112b, 112c, and 112d may be provided respectively in a second quadrant, a first quadrant, a third quadrant, and a fourth quadrant, which are formed by the second DTI structure d2.

The third pixel 113 may include the plurality of third photosensitive cells 113a, 113b, 113c, and 113d that are two-dimensionally arranged in the first direction (y-direction) and the second direction (x-direction). Referring to FIG. 9, the plurality of third photosensitive cells 113a, 113b, 113c, and 113d may be electrically separated from each other by the third DTI structure d3. The third DTI structure d3 may have a cross shape, and the plurality of third photosensitive cells 113a, 113b, 113c, and 113d may be provided respectively in a second quadrant, a first quadrant, a third quadrant, and a fourth quadrant, which are formed by the third DTI structure d3.

The fourth pixel 113 may include the plurality of fourth photosensitive cells 114a, 114b, 114c, and 114d that are two-dimensionally arranged in the first direction (y-direction) and the second direction (x-direction). Referring to FIG. 9, the plurality of fourth photosensitive cells 114a, 114b, 114c, and 114d may be electrically separated from each other by the fourth DTI structure d4. The fourth DTI structure d4 may have a cross shape, and the plurality of fourth photosensitive cells 114a, 114b, 114c, and 114d may be provided respectively in a second quadrant, a first quadrant, a third quadrant, and a fourth quadrant, which are formed by the fourth DTI structure d4.

In addition, referring to FIG. 9, the first pixel 111, the second pixel 112, the third pixel 113, and the fourth pixel 114 may be electrically separated from each other by an additional DTI structure d5. The additional DTI structure d5 may have a cross shape, and the first to fourth pixels 111 to 114 may be provided respectively in a second quadrant, a first quadrant, a third quadrant, and a fourth quadrant, which are formed by the additional DTI structure d5.

The filter layer 120 may include a plurality of filters 121, 122, 123, and 124 (hereinafter, also referred to as a first filter 121, a second filter 122, a third filter 123, and a fourth filter 124), each of which transmits only light of a certain wavelength band and absorbs or reflects light of other wavelength bands. The plurality of filters 121, 122, 123, and 124 may be provided to correspond to the plurality of pixels 111, 112, 113, and 114, respectively. For example, the filter layer 120 may include the first filter 121 arranged on the first pixel 111 to transmit only light of the first wavelength band, the second filter 122 arranged on the second pixel 112 to transmit only light of the second wavelength band that is different from the first wavelength band, the third filter 123 arranged on the third pixel 113 to transmit only light of the third wavelength band that is different from the first and second wavelength bands, and the fourth filter 124 arranged on the fourth pixel 114 to transmit only light of the first wavelength band.

Accordingly, the first filter 121 and the second filter 122 may be alternately arranged in the first direction (y-direction), and the third filter 123 and the fourth filter 124 may be alternately arranged in a cross-section at a different position in the second direction (x-direction) from the cross-section in which the first filter 121 and the second filter 122 are arranged. For example, the first and fourth filters 121 and 124 may transmit only green light, the second filter 122 may transmit only blue light, and the third filter 123 may transmit only red light. The first to fourth filters 121 to 124 may be two-dimensionally arranged in the first direction (y-direction) and the second direction (x-direction).

The nanophotonic microlens array 130 may be arranged on the filter layer 120. The nanophotonic microlens array 130 may include a plurality of nanophotonic microlenses 131, 132, 133, and 134 (hereinafter, also referred to as a first nanophotonic microlens 131, a second nanophotonic microlens 132, a third nanophotonic microlens 133, and a fourth nanophotonic microlens 134) that are two-dimensionally arranged. The plurality of nanophotonic microlenses 131, 132, 133, and 134 may correspond to the plurality of filters 121, 122, 123, and 124, respectively, and may correspond to the plurality of pixels 111, 112, 113, and 114, respectively. For example, the nanophotonic microlens array 130 may include the first nanophotonic microlens 131 arranged on the first filter 121, the second nanophotonic microlens 132 arranged on the second filter 122, the third nanophotonic microlens 133 arranged on the third filter 123, and the fourth nanophotonic microlens 134 arranged on the fourth filter 124. Accordingly, the first nanophotonic microlens 131 and the second nanophotonic microlens 132 may be alternately arranged in the first direction (y-direction), and the third nanophotonic microlens 133 and the fourth nanophotonic microlens 134 may be alternately arranged in a cross-section at a different position in the second direction (x-direction) from the cross-section in which the nanophotonic microlens 131 and the second nanophotonic microlens 132 are arranged.

The first to fourth nanophotonic microlenses 131 to 134 may be two-dimensionally arranged in the first direction (y-direction) and the second direction (x-direction) to face the corresponding filters and the corresponding pixels, respectively. For example, the first pixel 111, the first filter 121, and the first nanophotonic microlens 131 may be arranged to face each other in a third direction (z-direction), which is perpendicular to the first direction (y-direction) and the second direction (x-direction). In addition, the second pixel 112, the second filter 122, and the second nanophotonic microlens 132 may be arranged to face each other in the third direction (z-direction), the third pixel 113, the third filter 123, and the third nanophotonic microlens 133 may be arranged to face each other in the third direction (z-direction), and the fourth pixel 114, the fourth filter 124, and the fourth nanophotonic microlens 134 may be arranged to face each other in the third direction (z-direction). In this case, the first to fourth nanophotonic microlenses 131 to 134 and the first to fourth DTI structures d1 to d4 may be arranged such that the center points of the first to fourth nanophotonic microlenses 131 to 134 are located on the same axis as the center points of the first to fourth DTI structures d1 to d4 in the third direction (z-direction), respectively.

The first to fourth nanophotonic microlenses 131 to 134 may focus the incident light Lf1 on the corresponding pixels among the plurality of pixels 111, 112, 113, and 114, respectively. For example, the first nanophotonic microlens 131 may focus the incident light Lf1 on the first pixel 111. Similarly, the second to fourth nanophotonic microlenses 132, 133, and 134 may focus the incident light Lf1 on the second to fourth pixels 112, 113, and 114, respectively.

In the incident light Lf1 that is focused on the sensor substrate 110 by the nanophotonic microlens array 130, only light of the first wavelength band may be transmitted through the first and fourth filters 121 and 124 to be collected in the first and fourth pixels 111 and 114, only light of the second wavelength band may be transmitted through the second filter 122 to be collected in the second pixel 112, and only light of the third wavelength band may be transmitted through the third filter 123 to be collected in the third pixel 113.

The plurality of nanophotonic microlenses 131, 132, 133, and 134 may be formed to focus the incident light Lf1 respectively on a plurality of regions, which are spaced apart, toward the DTI structures d1, d2, d3, and d4, respectively, from the centers of the plurality of photosensitive cells 111a, 111b, 111c, 111d, 112a, 112b, 112c, 112d, 113a, 113b, 113c, 113d, 114a, 114b, 114c, and 114d included in the corresponding pixels 111, 112, 113, and 114, respectively. In this case, portions of the incident light Lf1 transmitted through the plurality of nanophotonic microlenses 131, 132, 133, and 134, respectively, may be incident on the DTI structures d1, d2, d3, and d4, respectively.

For example, as illustrated in FIG. 8, the first nanophotonic microlens 131 may focus the incident light Lf1 on a plurality of regions, which are spaced apart from the centers of the plurality of first photosensitive cells 111a, 111b, 111c, and 111d, respectively, toward the first DTI structure d1. In this case, a portion of the incident light Lf1 transmitted through the first nanophotonic microlens 131 may be incident on the first DTI structure d1.

The first nanophotonic microlens 131 may be formed such that light transmitted through the first nanophotonic microlens 131 has a phase profile having a plurality of convex regions. In this case, the light transmitted through the first nanophotonic microlens 131 may be collected more on the plurality of first photosensitive cells 111a, 111b, 111c, and 111d than on the first DTI structure d1. As described above, the amount of the incident light Lf1 collected on the center of the first DTI structure d1 may be reduced by the first nanophotonic microlens 131. Similarly, the second to fourth nanophotonic microlenses 132, 133, and 134 may also be formed such that light transmitted respectively through the second to fourth nanophotonic microlenses 132, 133, and 134 has a phase profile having a plurality of convex regions, and accordingly, the amount of the incident light Lf1 collected on the centers of the second to fourth DTI structures d2, d3, and d4 may be reduced.

Each of the plurality of nanophotonic microlenses 131, 132, 133, and 134 may include a convex lens structure having a plurality of convex portions. For example, each of the plurality of nanophotonic microlenses 131, 132, 133, and 134 may include a single convex lens structure in which a plurality of convex lens-shaped portions, the number of which corresponds to the number of photosensitive cells included in each of the pixels corresponding to the nanophotonic microlens, partially overlap each other about the center point of the nanophotonic microlens. Accordingly, the number of convex portions included in each of the plurality of nanophotonic microlenses 131, 132, 133, and 134 may be equal to the number of photosensitive cells included in the corresponding one of the plurality of pixels 111, 112, 113, and 114, which corresponds to each of the plurality of nanophotonic microlens 131, 132, 133, and 134.

For example, as illustrated in FIGS. 7 and 8, the first nanophotonic microlens 131 may include a single convex lens structure in which a plurality of convex lens-shaped portions, the number of which corresponds to the number of first photosensitive cells 111a, 111b, 111c, and 111d included in the corresponding first pixel 111, partially overlap each other about the center point of the first nanophotonic microlens 131. For example, the first pixel 111 may include four first photosensitive cells 111a, 111b, 111c, and 111d, and the first nanophotonic microlens 131 may include a single convex lens structure in which four convex lens-shaped portions partially overlap each other about the center point of first nanophotonic microlens 131. In this case, the first nanophotonic microlens 131 has the plurality of convex lens-shaped portions that overlap each other without gaps about the center point thereof, and accordingly, no opening may be formed in the center of the first nanophotonic microlens 131. Accordingly, a change in phase of light passing through the center of the first nanophotonic microlens 131 may occur.

In addition, the degree of overlapping of the four convex lens-shaped portions of the first nanophotonic microlens 131 may be variously designed as necessary. As the degree of overlapping of the four convex lens-shaped portions of the first nanophotonic microlens 131 increases, the amount of the incident light Lf1 on the first DTI structure d1 increases and the amount of light collected on the plurality of first photosensitive cells 111a, 111b, 111c, and 111d decreases. On the other hand, as the degree of overlapping of the four convex lens-shaped portions of the first nanophotonic microlens 131 decreases, the amount of the incident light Lf1 on the first DTI structure d1 decreases and the amount of light collected on the plurality of first photosensitive cells 111a, 111b, 111c, and 111d increases.

Similar to the first nanophotonic microlens 131, each of the second to fourth nanophotonic microlenses 132, 133, and 134 may have a single convex lens structure in which a plurality of convex lens-shaped portions, the number of which corresponds to the number of photosensitive cells included in the corresponding pixel, i.e., the number of second photosensitive cells 112a, 112b, 112c, and 112d, the number of third photosensitive cells 113a, 113b, 113c, and 113d, or the number of fourth photosensitive cells 114a, 114b, 114c, and 114d included in the corresponding one of the plurality of pixels 112, 113, and 114, partially overlap each other about the center point of the nanophotonic microlens.

The first nanophotonic microlens 131 may have a concave portion in a boundary region where the plurality of convex portions overlap each other. For example, the plurality of convex portions of the first nanophotonic microlens 131 may overlap each other in a first region corresponding to the first DTI structure d1, and the first region of the first nanophotonic microlens 131 may be concave. The plurality of convex portions may be formed in a second region that is the remaining region other than the first region in the first nanophotonic microlens 131. In this case, the plurality of convex portions included in the first nanophotonic microlens 131 may be symmetrically distributed with respect to the first region corresponding to the first DTI structure d1 of the first nanophotonic microlens 131.

Similarly, each of the second to fourth nanophotonic microlenses 132, 133, and 134 may also have a concave portion in a boundary region where the plurality of convex portions overlap each other. For example, the second to fourth nanophotonic microlenses 132, 133, and 134 may have the concave portions in first regions corresponding to the second to fourth DTI structures d2, d3, and d4, respectively. In addition, the plurality of convex portions of each of the second to fourth nanophotonic microlenses 132, 133, and 134 may be formed in a second region that is the remaining region other than the first region in each of the second to fourth nanophotonic microlenses 132, 133, and 134. In this case, the plurality of convex portions included in each of the second to fourth nanophotonic microlenses 132, 133, and 134 may be symmetrically distributed with respect to the first region corresponding to the second, third, or fourth DTI structure d2, d3, or d4 of the nanophotonic microlens.

Furthermore, each of the plurality of nanophotonic microlenses 131, 132, 133, and 134 may be formed such that maximum points of the plurality of convex portions are provided in a third region, which corresponds to regions between the DTI structure d1, d2, d3, or d4 of each of the plurality of nanophotonic microlenses 131, 132, 133, and 134 and the center points of the plurality of photosensitive cells, i.e., the plurality of first photosensitive cells 111a, 111b, 111c, and 111d, the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d.

For example, referring to FIG. 8, maximum points s1, s2, s3, and s4 of the plurality of convex portions of the first nanophotonic microlens 131 may be provided in a third region an, which corresponds to regions between the first DTI structure d1 and center points c1, c2, c3, and c4 of the plurality of first photosensitive cells 111a, 111b, 111c, and 111d. In this case, for example, the maximum points s1, s2, s3, and s4 of the plurality of convex portions of the first microlens 131 may be formed to be closer to the center points c1, c2, c3, and c4 of the plurality of first photosensitive cells 111a, 111b, 111c, and 111d, than to the center point of the first DTI structure d1. However, embodiments are not limited thereto, and the maximum points s1, s2, s3, and s4 of the plurality of convex portions of the first nanophotonic microlens 131 may be formed to be closer to the center point of the first DTI structure d1 than to the center points c1, c2, c3, and c4 of the plurality of first photosensitive cells 111a, 111b, 111c, and 111d. In addition, the maximum points s1, s2, s3, and s4 of the plurality of convex portions of the first nanophotonic microlens 131 may be symmetrically distributed with respect to the center point of the first DTI structure d1.

As described above, the maximum points s1, s2, s3, and s4 of the plurality of convex portions of the first nanophotonic microlens 131 are formed to be spaced apart from the center points c1, c2, c3, and c4 of the plurality of first photosensitive cells 111a, 111b, 111c, and 111d, respectively, toward the center point of the first DTI structure d1, and thus, a portion of the incident light Lf1 may be collected on the central region of the first DTI structure d1 in contact with the plurality of first photosensitive cells 111a, 111b, 111c, and 111d, and the other portions of the incident light Lf1 may be collected on the plurality of first photosensitive cells 111a, 111b, 111c, and 111d, respectively.

In this case, because one pixel, e.g., the first pixel 111, includes the plurality of first photosensitive cells 111a, 111b, 111c, and 111d, each of which independently senses light, an autofocus signal may be provided in a phase-detection autofocus manner by using a difference between signals output from the plurality of first photosensitive cells 111a, 111b, 111c, and 111d by the light incident on the central region of the first DTI structure d1 that is in contact with the plurality of first photosensitive cells 111a, 111b, 111c, and 111d.

In addition, because the other portions of the incident light Lf1 deviate from the central region of the first DTI structure d1 that is in contact with the plurality of first photosensitive cells 111a, 111b, 111c, and 111d, and is collected on the plurality of first photosensitive cells 111a, 111b, 111c, and 111d, light loss that may occur when the incident light Lf1 is incident intensively on the central region of the first DTI structure d1 in contact with the plurality of first photosensitive cells 111a, 111b, 111c, and 111d, and thus most of the incident light Lf1 is absorbed by the first DTI structure d1, may be suppressed.

Similarly, the maximum points of the plurality of convex portions of each of the second to fourth nanophotonic microlenses 132, 133, and 134 may be provided in a third region, which corresponds to regions between the second, third, or fourth DTI structure d2, d3, or d4 and the central points of the corresponding photosensitive cells, i.e., the central points of the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d.

Referring to FIGS. 10 and 11, the light transmitted through the first nanophotonic microlens 131 may be collected on the first pixel 111 through the first filter 121. In this case, light transmitted through the concave central region of the first nanophotonic microlens 131 may be collected on the central region of the first DTI structure d1 included in the first pixel 111, and light transmitted through the plurality of convex portions of the first nanophotonic microlens 131 may be collected on the first photosensitive cells 111a, 111b, and 111c included in the first pixel 111. Although FIGS. 10 and 11 illustrate only the first photosensitive cells 111a, 111b, and 111c provided in the first to third quadrants formed by the first DTI structure d1, light may also be collected on the first photosensitive cell 111d provided in the fourth quadrant, similarly to the light collected on the first photosensitive cells 111a, 111b, and 111c provided in the first to third quadrants. In addition, similar to the first nanophotonic microlens 131, light transmitted through the second to fourth nanophotonic microlenses 132, 133, and 134 may be collected on the second to fourth pixels 112, 113, and 114, respectively.

Each of the plurality of nanophotonic microlenses 131, 132, 133, and 134 may be formed such that light transmitted through each of the plurality of nanophotonic microlenses 131, 132, 133, and 134 has a phase profile having a plurality of convex regions. For example, referring to FIGS. 12 and 13, light transmitted through the first nanophotonic microlens 131 may have a phase profile in which a plurality of convex regions overlap each other. In this case, the number of convex regions included in the phase profile of the light transmitted through the first nanophotonic microlens 131 may be equal to the number of photosensitive cells 111a, 111b, 111c, and 111d included in the first pixel 111 corresponding to the first nanophotonic microlens 131. The plurality of convex regions in the phase profile of the light transmitted through the first nanophotonic microlens 131 may be regions distinguished from each other with the concave region therebetween, and may be two-dimensionally arranged in the first direction (y-direction) and the second direction (x-direction). The plurality of convex regions may be two-dimensionally arranged and overlap each other by a certain amount, and the region in which the plurality of convex regions overlap each other may be more concave than the plurality of convex regions.

Similarly, light transmitted through each of the second to fourth nanophotonic microlenses 132, 133, and 134 may have a phase profile in which a plurality of convex regions overlap each other. In this case, the number of convex regions in the phase profile of the light transmitted through each of the second to fourth nanophotonic microlenses 132, 133, and 134 may be equal to the number of photosensitive cells, i.e., the number of second photosensitive cells 112a, 112b, 112c, and 112d, the number of third photosensitive cells 113a, 113b, 113c, and 113d, or the number of fourth photosensitive cells 114a, 114b, 114c, and 114d, included in the pixel 112, 113, or 114 corresponding to the second to fourth nanophotonic microlenses 132, 133, and 134.

Each of the plurality of nanophotonic microlenses 131, 132, 133, and 134 may be formed such that light transmitted through the first region corresponding to the first, second, third, or fourth DTI structure d1, d2, d3, or d4 of the plurality of nanophotonic microlenses 131, 132, 133, and 134 has a phase profile having a region where the plurality of convex regions overlap each other, and light transmitted through the second region that is the remaining region other than the first region of the plurality of nanophotonic microlenses 131, 132, 133, and 134 has a phase profile having a plurality of convex regions. In addition, each of the plurality of nanophotonic microlenses 131, 132, 133, and 134 may be formed such that the light transmitted through each of the plurality of nanophotonic microlenses 131, 132, 133, and 134 has a phase profile including a plurality of convex regions that are symmetrically distributed with respect the first region corresponding to the first, second, third, or fourth DTI structure d1, d2, d3, or d4.

For example, referring to FIGS. 8 and 12, light transmitted through a first region a1 corresponding to the second DTI structure d2 of the second nanophotonic microlens 132 may have a phase profile having a region where a plurality of convex regions overlap each other, and light transmitted through a second region a2 that is the remaining region other than the first region a1 in the second nanophotonic microlens 132 may have a phase profile having a region having the plurality of convex regions. Although FIGS. 8 and 12 illustrate that the first region a1 and the second region a2 are as partial regions of the second nanophotonic microlens 132, which correspond to the first quadrant and the second quadrant formed by the second DTI structure d2, this is merely an example for convenience of description, and the first region a1 may refer to all regions corresponding to the second DTI structure d2 of the second nanophotonic microlens 132, and the second region a2 may refer to the remaining regions other than the regions corresponding to the second DTI structure d2 of the second nanophotonic microlens 132. In this case, the light transmitted through the second nanophotonic microlens 132 may have a phase profile including a plurality of convex regions that are symmetrically distributed with respect the first region a1.

Each of the plurality of nanophotonic microlenses 131, 132, 133, and 134 may be formed such that the phase profile of light transmitted through the third region, which corresponds to regions between each of the DTI structure d1, d2, d3, or d4 of the plurality of nanophotonic microlenses 131, 132, 133, and 134 and the center points of the plurality of photosensitive cells, i.e., the plurality of first photosensitive cells 111a, 111b, 111c, and 111d, the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d, has a plurality of maximum points.

For example, referring to FIGS. 8 and 12 to 15, light transmitted through the third region an of the first nanophotonic microlens 131 may have a phase profile including a plurality of maximum points. In this case, the phases of light transmitted through the maximum points s1, s2, s3, and s4 included in the third region an of the first nanophotonic microlens 131 may have maximum values. In addition, the number of maximum points included in the phase profile of the light transmitted through the third region an of the first nanophotonic microlens 131 may be equal to the number of maximum points s1, s2, s3, and s4 included in the third region an of the first nanophotonic microlens 131.

Referring to FIGS. 8 and 12, the phase of light transmitted through a minimum point p1 corresponding to the center between the center points c2 and c1 of two photosensitive cells, that is, the photosensitive cells 111b and 111a, provided in the first and second quadrants formed by the first DTI structure d1 in the first nanophotonic microlens 131 may have a minimum value. Similarly, referring to FIGS. 8 and 13, the phase of light transmitted through a minimum point p2 corresponding to the center between the center points c1 and c3 of two photosensitive cells, that is, the photosensitive cells 111a and 111c, provided in the second and third quadrants formed by the first DTI structure d1 in the first nanophotonic microlens 131 may have a minimum value. Regions corresponding to the minimum points p1 and p2 of the first nanophotonic microlens 131 may correspond to a portion of the first DTI structure d1.

In addition, referring to FIGS. 8 and 14, the phases of light transmitted through two maximum points s1 and s4 provided between the center points c1 and c4 of two photosensitive cells, that is, the photosensitive cells 111a and 111d, provided in the second and fourth quadrants formed by the first DTI structure d1 in the first nanophotonic microlens 131 may have maximum values. Furthermore, referring to FIGS. 8 and 15, the phases of light transmitted through two maximum points s2 and s3 provided between the center points c2 and c3 of two photosensitive cells, that is, the photosensitive cells 111b and 111c, provided in the first and third quadrants formed by the first DTI structure d1 in the first nanophotonic microlens 131 may have maximum values.

Similar to the first nanophotonic microlens 131, the light transmitted through the third region of each of the second to fourth nanophotonic microlenses 132, 133, and 134 may have a phase profile including a plurality of maximum points.

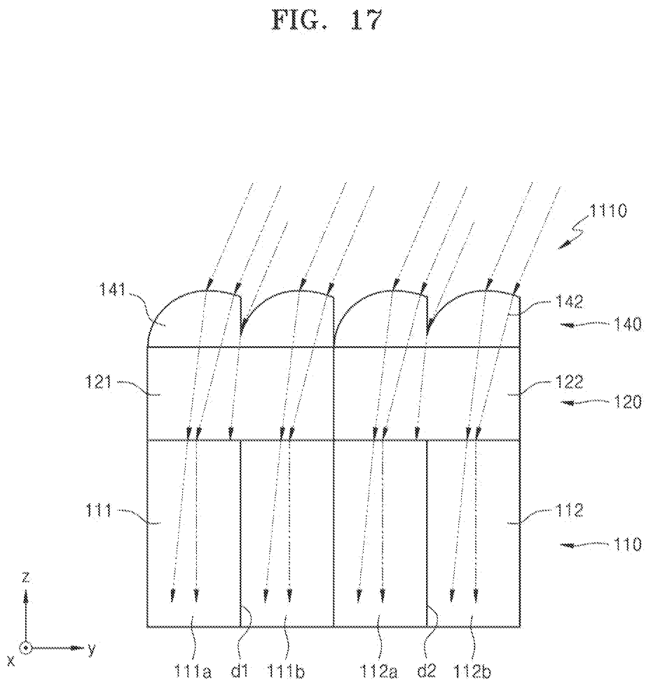

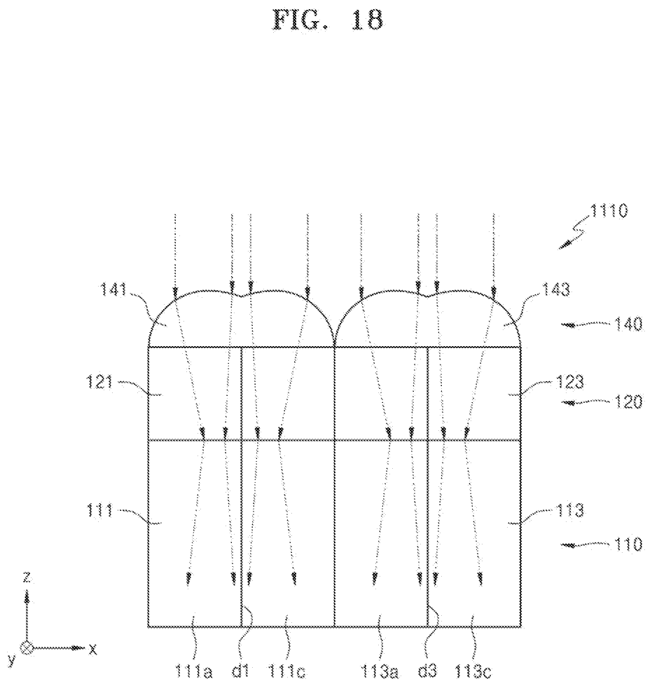

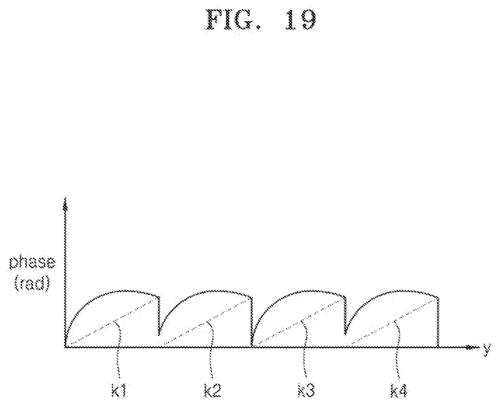

FIG. 16 is a plan view illustrating an example configuration of a peripheral portion of a pixel array 1110 included in the optical sensor 1000, according to another example embodiment. FIG. 17 is a cross-sectional view taken along line E-E′ in the peripheral portion of the pixel array 1110 of FIG. 16. FIG. 18 is a cross-sectional view taken along line F-F′ in the peripheral portion of the pixel array 1110 of FIG. 16. FIG. 19 is a diagram illustrating a phase profile of light transmitted through a portion along line E-E′ in the peripheral portion of the pixel array 1110 of FIG. 16.

The pixel array 1110 of FIGS. 16 to 18 may be substantially the same as the pixel array 1100 of FIG. 7, except that the configuration of a nanophotonic microlens array 140 is different from that of the nanophotonic microlens array 130 of FIG. 7. In FIG. 16, for convenience of description, the sensor substrate 110 and the filter layer 120 included in the pixel array 1110 are omitted. In describing FIGS. 16 to 18, descriptions that are provided in connection with FIGS. 1 to 15 are omitted. Also, in describing FIGS. 16 to 18, the reference numerals of the components illustrated in FIGS. 1 to 15 are used.

The configuration of the central region aa1 (see FIG. 6) of the nanophotonic microlens array 140 included in the pixel array 1110 of FIGS. 16 to 18 may be the same as that of the nanophotonic microlens array 130 included in the pixel array 1100 of FIG. 7.

According to another example embodiment, the configuration of the peripheral regions aa2 and aa3 (see FIG. 6) of the nanophotonic microlens array 140 may be different from that of the nanophotonic microlens array 130. However, the configuration of the nanophotonic microlens array 140 may be substantially the same as that of the nanophotonic microlens array 130 of FIG. 7 in that each of a plurality of nanophotonic microlenses 141, 142, 143, and 144 (hereinafter, also referred to as first to fourth nanophotonic microlenses 141 to 144) arranged in the peripheral regions aa2 and aa3 of the nanophotonic microlens array 140 includes a plurality of convex portions, first regions corresponding to DTI structures of the plurality of nanophotonic microlenses 141, 142, 143, and 144 arranged in the peripheral regions aa2 and aa3 of the nanophotonic microlens array 140 are concave, and the plurality of convex portions are formed in a second region that is the remaining region other than the first region.

Hereinafter, characteristics of the plurality of nanophotonic microlenses 141, 142, 143, and 144 arranged in the peripheral regions aa2 and aa3 of the nanophotonic microlens array 140, which are distinguished from the configuration of the nanophotonic microlens array 130 of FIG. 7, will be described.

Referring to FIGS. 16 to 18, each of the plurality of nanophotonic microlenses 141, 142, 143, and 144 arranged in the peripheral regions aa2 and aa3 of the nanophotonic microlens array 140 may be formed such that maximum points of a plurality of convex portions of each of the plurality of nanophotonic microlenses 141, 142, 143, and 144 are spaced apart from the respective center points of the plurality of photosensitive cells, i.e., the plurality of first photosensitive cells 111a, 111b, 111c, and 111d, the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d, in the first direction (y-direction), and are distributed to be closer to the center line of the DTI structure in the first direction (y-direction) than to each of the center points of first photosensitive cells 111a, 111b, 111c, and 111d, the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d.

For example, the first nanophotonic microlens 141 arranged in the peripheral regions aa2 and aa3 of the nanophotonic microlens array 140 may be formed such that maximum points s5, s6, s7, and s8 of the plurality of convex portions of the first nanophotonic microlens 141 are spaced apart from the center points c1, c2, c3, and c4 of the plurality of first photosensitive cells 111a, 111b, 111c, and 111d in the first direction (y-direction), and are distributed closer to a center line dcl of the first DTI structure d1 in the first direction (y-direction) than to the center points c1, c2, c3, and c4 of the plurality of first photosensitive cells 111a, 111b, 111c, and 111d.

In this case, unlike the maximum points s1, s2, s3, and s4 of the first nanophotonic microlens 131 of FIGS. 7 and 8, the maximum points s5, s6, s7, and s8 of the first nanophotonic microlens 141 arranged in the peripheral regions aa2 and aa3 of the nanophotonic microlens array 140 may be distributed to be spaced apart from the center points c1, c2, c3, and c4 of the plurality of first photosensitive cells 111a, 111b, 111c, and 111d all in the first direction (y-direction).

As illustrated in FIG. 17, the first nanophotonic microlens 141 arranged in the peripheral regions aa2 and aa3 of the nanophotonic microlens array 140 may include a plurality of convex portions periodically arranged in the first direction (y-direction). In this case, the maximum points of the plurality of convex portions included in the first nanophotonic microlens 141 may be formed to be spaced apart from the center points of the plurality of photosensitive cells 111a, 111b, 111c, and 111d included in the corresponding first pixel 111 in the first direction (y-direction).

In this case, the phase profile of light transmitted through the first and second nanophotonic microlenses 141 and 142 in the first direction (y-direction), which are arranged in the peripheral regions aa2 and aa3 of the nanophotonic microlens array 140 and includes the plurality of convex portions are periodically arranged in the first direction (y-direction), may have a phase profile in which a linear phase profile inclined in the first direction (y-direction) and a convex phase profile are mixed together. For example, as illustrated in FIG. 19, the light transmitted through the first and second nanophotonic microlenses 141 and 142 arranged in the peripheral regions aa2 and aa3 of the nanophotonic microlens array 140 may have a phase profile in which a plurality of inclined linear phase profiles k1, k2, k3, and k4 and a plurality of convex phase profiles are mixed with each other, respectively, in the first direction (y-direction). Accordingly, even when the CRA of the light incident on the first and second nanophotonic microlenses 141 and 142 arranged in the peripheral regions aa2 and aa3 of the nanophotonic microlens array 140 is greater than 0°, the difference between the amount of light collected on the plurality of photosensitive cells arranged in the peripheral regions aa2 and aa3 of the nanophotonic microlens array 140 and the amount of light collected on the plurality of photosensitive cells arranged in the central region aa1 may be minimized.

Moreover, as illustrated in FIGS. 16 and 18, the plurality of convex portions of the first nanophotonic microlens 141 arranged in the peripheral regions aa2 and aa3 of the nanophotonic microlens array 140 may be symmetrically distributed in the second direction (x-direction) with respect to the center line dcl of the first DTI structure d1 in the first direction (y-direction). In this case, the phase profile, in the second direction (x-direction), of the light transmitted through the first nanophotonic microlens 141, which includes the plurality of convex portions symmetrically arranged in the second direction (x-direction) and is arranged in the peripheral regions aa2 and aa3 of the nanophotonic microlens array 140, may be the same as illustrated in FIG. 13.

In addition, as the distance between the central region aa1 of the nanophotonic microlens array 140 and the first nanophotonic microlens 141 increases, the distances between the maximum points s5, s6, s7, and s8 of the first nanophotonic microlens 141 and the center points c1, c2, c3, and c4 of the plurality of first photosensitive cells 111a, 111b, 111c, and 111d in the first direction (y-direction) may also increase. For example, the nanophotonic microlens array 140 may include a 1-1st nanophotonic microlens arranged at one point in the peripheral regions aa2 and aa3, and a 1-2nd nanophotonic microlens arranged farther from the central region aa1 than the 1-1st nanophotonic microlens. In this case, the distance between the maximum points of the plurality of convex portions of the 1-2nd nanophotonic microlens and the center points of the plurality of photosensitive cells corresponding to the 1-2nd nanophotonic microlens may be greater than the distance between the maximum points of the plurality of convex portions the 1-1st nanophotonic microlens and the center points of the plurality of photosensitive cells corresponding to the 1-1st nanophotonic microlens. Accordingly, despite the fact that the CRA of incident light increases toward the edge of the nanophotonic microlens array 140, the phase change of the incident light may also increase to that extent, and consequently, the difference between the amount of light collected on the plurality of photosensitive cells arranged in the peripheral regions aa2 and aa3 of the nanophotonic microlens array 140 and the amount of light collected on the plurality of photosensitive cells arranged in the central region aa1 may be minimized.

Furthermore, a first slope of a linear phase profile inclined in the first direction (y-direction) of light transmitted through the 1-1st nanophotonic microlens arranged at one point in the peripheral regions aa2 and aa3 included in the nanophotonic microlens array 140 may be less than a second slope of a linear phase profile inclined in the first direction (y-direction) of light transmitted through the 1-2nd nanophotonic microlens arranged farther from the central region aa1 than the 1-1st nanophotonic microlens.

Similarly, the second to fourth nanophotonic microlenses 142, 143, and 144 arranged in the peripheral regions aa2 and aa3 of the nanophotonic microlens array 140 may be formed such that maximum points of each of the second to fourth nanophotonic microlenses 142, 143, and 144 are spaced apart from the respective center points of the plurality of photosensitive cells 112a, 112b, 112c, 112d, 113a, 113b, 113c, 113d, 114a, 114b, 114c, and 114d in the first direction (y-direction), and are distributed to be closer to the respective center lines of the second to fourth DTI structures d2, d3, and d4 in the first direction (y-direction) than to the center points of the plurality of photosensitive cells corresponding to the second to fourth nanophotonic microlenses 142, 143, and 144.

In addition, the plurality of convex portions of the second to fourth nanophotonic microlenses 142, 143, and 144 arranged in the peripheral regions aa2 and aa3 of the nanophotonic microlens array 140 may be symmetrically distributed in the second direction (x-direction) with respect to the center lines of the second to fourth DTI structures d2, d3, and d4 in the first direction (y-direction), respectively.

Also, light incident on the left peripheral region aa2 among the peripheral regions aa2 and aa3 of the nanophotonic microlens array 140 is incident on the pixel array 1110 at an angle in the opposite direction to the direction of light incident on the right peripheral region aa3, with respect to the normal line of the pixel array 1110. Accordingly, the first to fourth nanophotonic microlenses 141 to 144 arranged in the left peripheral region aa2 of the nanophotonic microlens array 140 may have a shape inverted, in the first direction (y-direction), from the shape of the first to fourth nanophotonic microlens 141 to 144 arranged in the right peripheral region aa3.

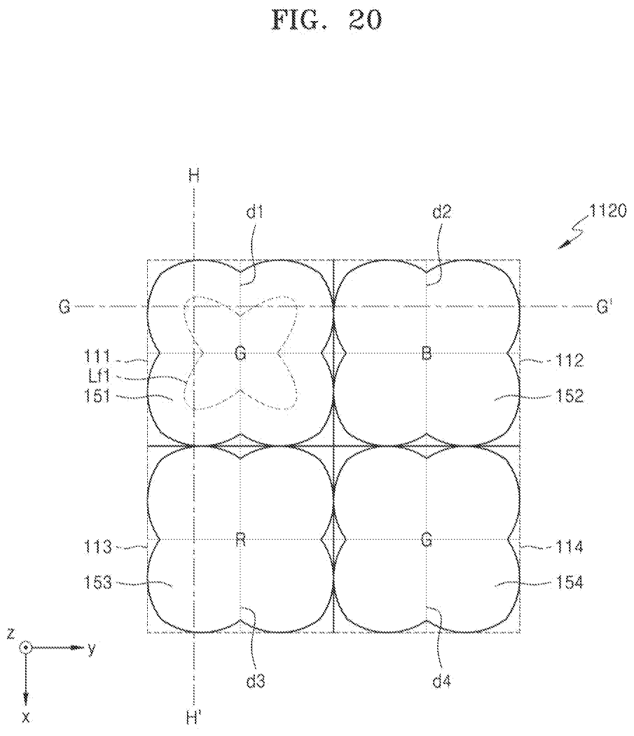

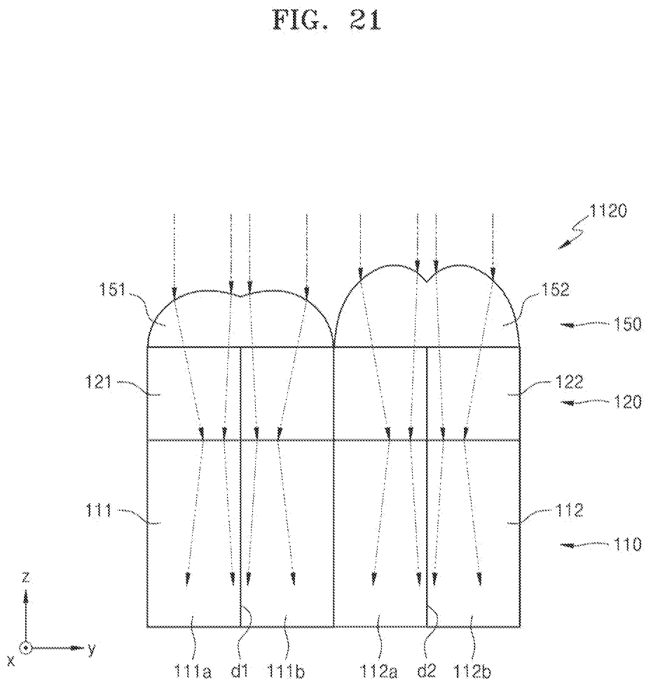

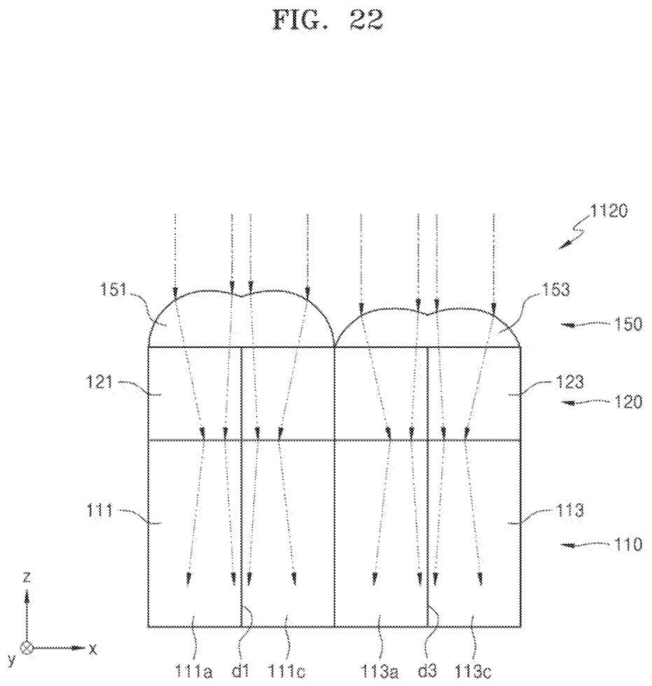

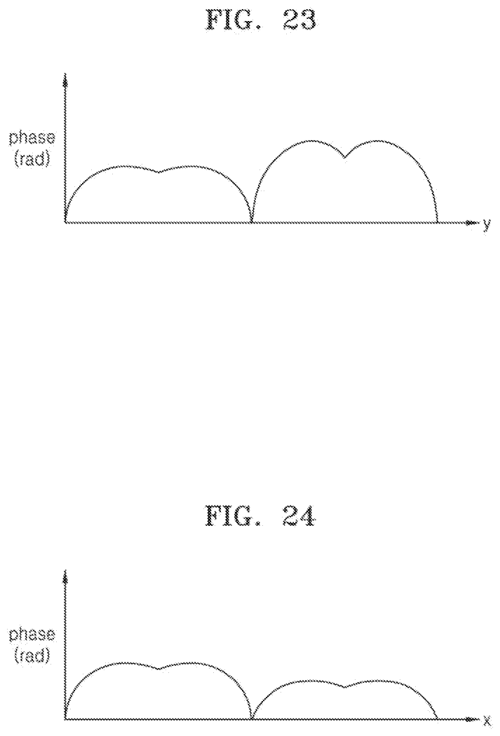

FIG. 20 is a plan view illustrating an example configuration of a pixel array 1120 included in the optical sensor 1000, according to another example embodiment. FIG. 21 is a cross-sectional view taken along line G-G′ of the pixel array 1120 of FIG. 20. FIG. 22 is a cross-sectional view taken along line H-H′ of the pixel array 1120 of FIG. 20. FIG. 23 is a diagram illustrating a phase profile of light transmitted through a portion along line G-G′ of the pixel array 1120 of FIG. 7. FIG. 24 is a diagram illustrating a phase profile of light transmitted through a portion along line H-H′ of the pixel array 1120 of FIG. 7.

The pixel array 1120 of FIGS. 20 to 22 may be substantially the same as the pixel array 1100 of FIG. 7, except that a plurality of nanophotonic microlenses 151, 152, 153, and 154 (hereinafter, also referred to as first to fourth nanophotonic microlenses 151 to 154) included in a nanophotonic microlens array 150 have different shapes according to wavelengths of light sensed by corresponding pixels, unlike the nanophotonic microlens array 130 of FIG. 7. In FIG. 20, for convenience of description, the filter layer 120 included in the pixel array 1120 is omitted. In describing FIGS. 20 to 22, descriptions that are provided in connection with FIGS. 1 to 15 are omitted. Also, in describing FIGS. 20 to 22, the reference numerals of the components illustrated in FIGS. 1 to 15 are used.

Referring to FIGS. 20 to 22, the nanophotonic microlens array 150 may include the first nanophotonic microlens 151 and the fourth nanophotonic microlens 154 respectively corresponding to the first pixel 111 and the fourth pixel 114 that sense light of the first wavelength band, which is the green light region. The first and fourth nanophotonic microlenses 151 and 154 may correspond to the first filter 121 and the fourth filter 124, respectively. The first and fourth nanophotonic microlenses 151 and 154 may focus light on the first pixel 111 and the fourth pixel 114, respectively.

In addition, the nanophotonic microlens array 150 may include the second nanophotonic microlens 152 corresponding to the second pixel 112 that senses light of the second wavelength band, which is the blue light region. The second nanophotonic microlens 152 may correspond to the second filter 122. The second nanophotonic microlens 152 may focus light on the second pixel 112.

Furthermore, the nanophotonic microlens array 150 may include the third nanophotonic microlens 153 corresponding to the third pixel 113 that senses light of the third wavelength band, which is the red light region. The third nanophotonic microlens 153 may correspond to the third filter 123. The third nanophotonic microlens 153 may focus light on the third pixel 113.

Here, each of the plurality of nanophotonic microlenses 151, 152, 153, and 154 may have a plurality of convex portions, which are more convex as the wavelength band of light sensed by the corresponding pixel is shorter. For example, as illustrated in FIG. 21, a plurality of second convex portions of the second nanophotonic microlens 152 corresponding to the second pixel 112 that senses light of the second wavelength band, which is the blue light region, may be formed to be more convex than a plurality of first convex portions of the first nanophotonic microlens 151 corresponding to the first pixel 111 that senses light of the first wavelength band, which is the green light region. In addition, as illustrated in FIG. 22, the plurality of first convex portions of the first nanophotonic microlens 151 corresponding to the first pixel 111 that senses light of the first wavelength band, which is the green light region, may be formed to be more convex than a plurality of third convex portions of the third nanophotonic microlens 153 corresponding to the third pixel 113 that senses light of the third wavelength band, which is the red light region. Furthermore, a plurality of fourth convex portions of the fourth nanophotonic microlens 154 corresponding to the fourth pixel 114 that senses light of the first wavelength band, which is the green light region, may have the same shape as that of the plurality of first convex portions of the first nanophotonic microlens 151.

In this case, as illustrated in FIG. 23, a plurality of second convex regions included in the phase profile of light transmitted through the second nanophotonic microlens 152 may be more convex than a plurality of first convex regions included in the phase profile of light transmitted through the first nanophotonic microlens 151. For example, the phase change of the light transmitted through the second nanophotonic microlens 152 may be substantially greater than the phase change of the light transmitted through the first nanophotonic microlens 151.

In addition, as illustrated in FIG. 24, a plurality of first convex regions included in the phase profile of light transmitted through the first nanophotonic microlens 151 may be more convex than a plurality of third convex regions included in the phase profile of light transmitted through the third nanophotonic microlens 153. For example, the phase change of the light transmitted through the first nanophotonic microlens 151 may be substantially greater than the phase change of the light transmitted through the third nanophotonic microlens 153.

Furthermore, a plurality of fourth convex regions included in the phase profile of light transmitted through the fourth nanophotonic microlens 154 may have the same shape as the plurality of first convex regions included in the phase profile of the light transmitted through the first nanophotonic microlens 151.

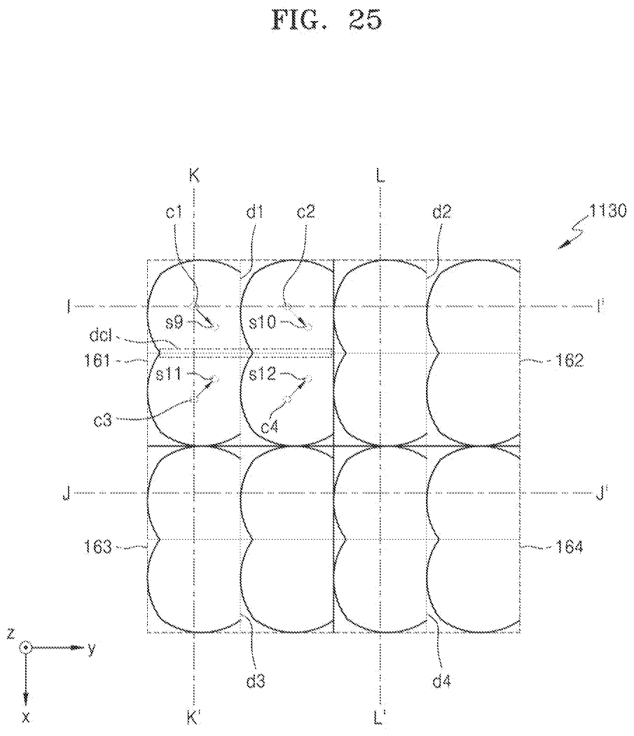

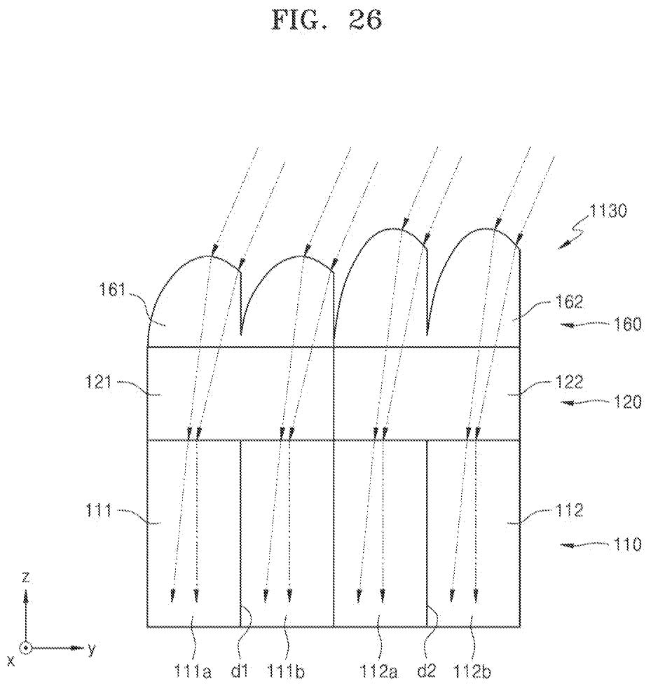

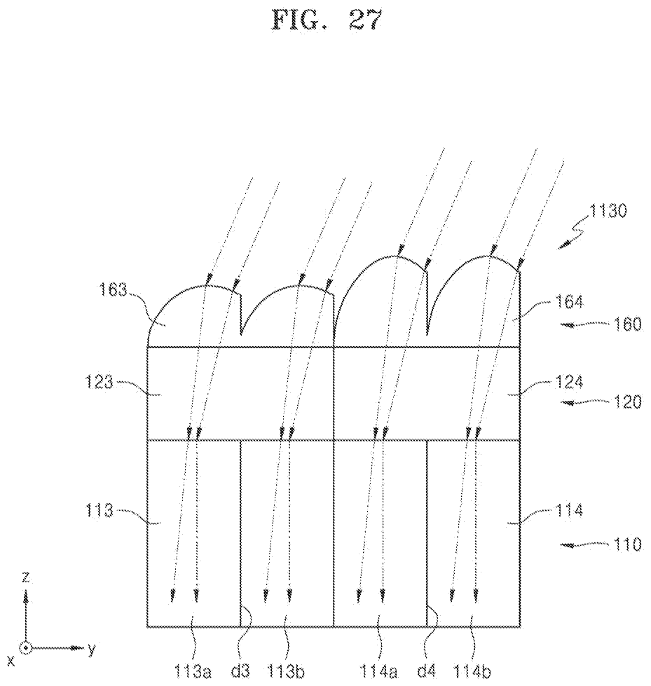

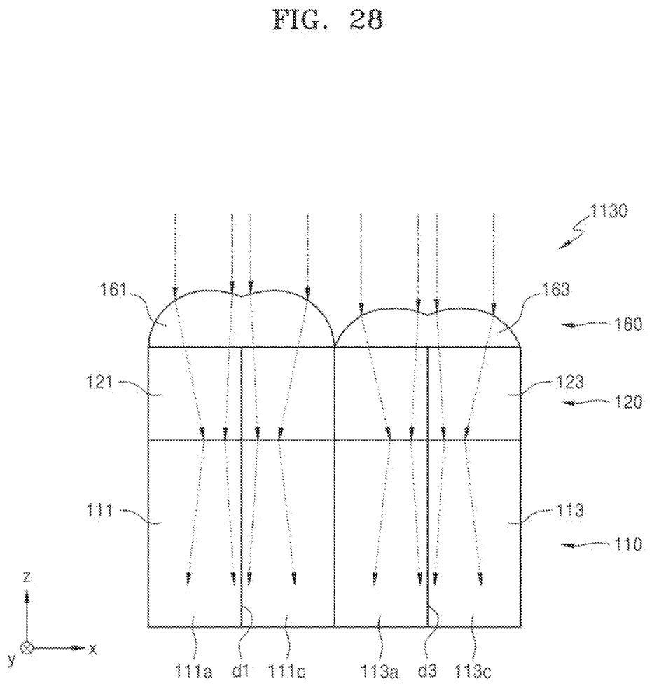

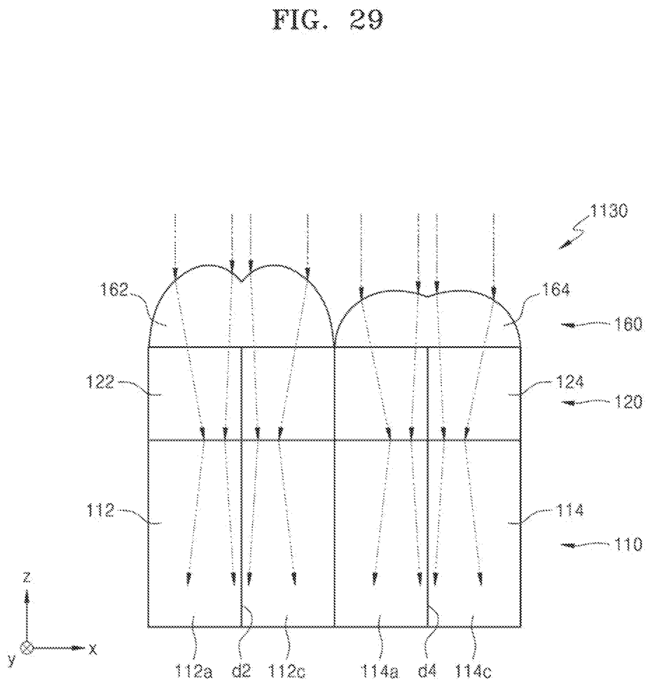

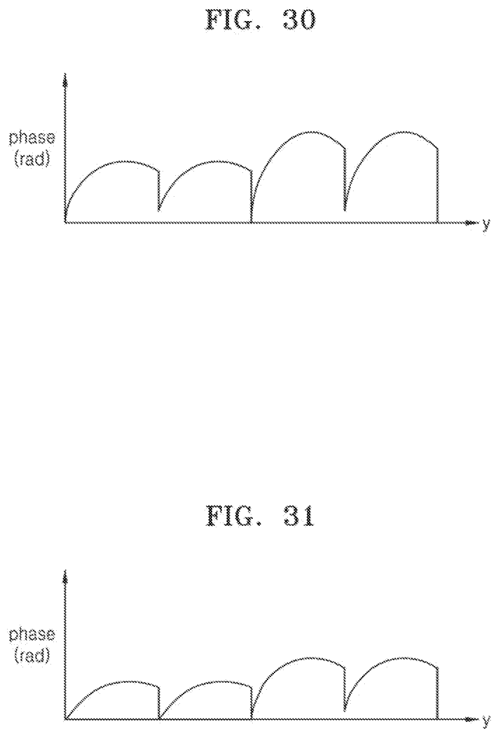

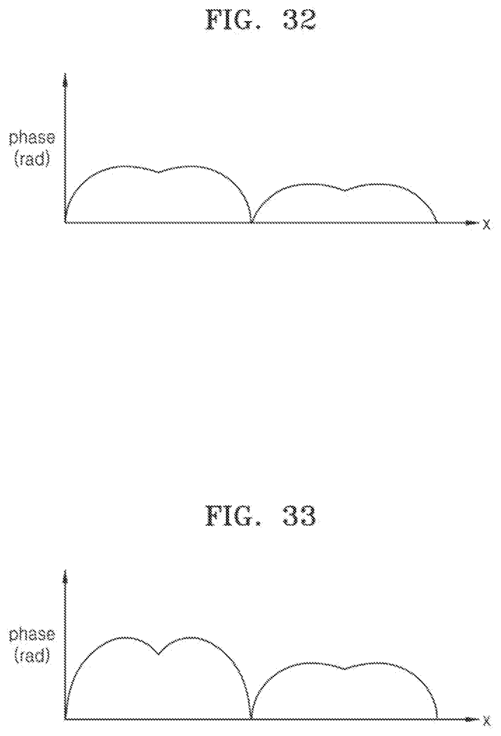

FIG. 25 is a plan view illustrating an example configuration of a pixel array 1130 included in the optical sensor 1000, according to another example embodiment. FIG. 26 is a cross-sectional view taken along line I-I′ of the pixel array 1130 of FIG. 25. FIG. 27 is a cross-sectional view taken along line J-J′ of the pixel array 1130 of FIG. 25. FIG. 28 is a cross-sectional view taken along line K-K′ of the pixel array 1130 of FIG. 25. FIG. 29 is a cross-sectional view taken along line L-L′ of the pixel array 1130 of FIG. 25. FIG. 30 is a diagram illustrating a phase profile of light transmitted through a portion along line I-I′ of the pixel array 1130 of FIG. 25. FIG. 31 is a diagram illustrating a phase profile of light transmitted through a portion along line J-J′ of the pixel array 1130 of FIG. 25. FIG. 32 is a diagram illustrating a phase profile of light transmitted through a portion along line K-K′ of the pixel array 1130 of FIG. 25. FIG. 33 is a diagram illustrating a phase profile of light transmitted through a portion along line L-L′ of the pixel array 1130 of FIG. 25.

The pixel array 1130 of FIGS. 25 to 29 may be substantially the same as the pixel array 1110 of FIG. 16, except that a plurality of nanophotonic microlenses 161, 162, 163, and 164 (hereinafter, also referred to as first to fourth nanophotonic microlenses 161 to 164) included in a nanophotonic microlens array 160 have different shapes according to wavelengths of light sensed by corresponding pixels, unlike the nanophotonic microlens array 140 of FIG. 16. In FIG. 25, for convenience of description, the sensor substrate 110 and the filter layer 120 included in the pixel array 1130 are omitted. In describing FIGS. 25 to 29, descriptions that are provided in connection with FIGS. 1 to 19 are omitted. Also, in describing FIGS. 25 to 29, the reference numerals of the components illustrated in FIGS. 1 to 15 are used.

Referring to FIGS. 25 to 29, each of the plurality of nanophotonic microlenses 161, 162, 163, and 164 arranged in the peripheral regions aa2 and aa3 of the nanophotonic microlens array 160 may be formed such that maximum points of a plurality of convex portions of each of the plurality of nanophotonic microlenses 161, 162, 163, and 164 are spaced apart from the respective center points of the plurality of photosensitive cells, i.e., the plurality of first photosensitive cells 111a, 111b, 111c, and 111d, the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d, in the first direction (y-direction), and are distributed to be closer to the center line of the DTI structure d1, d2, d3, or d4 in the first direction (y-direction) than to each of the center points of first photosensitive cells 111a, 111b, 111c, and 111d, the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d.

For example, the first nanophotonic microlens 161 arranged in the peripheral regions aa2 and aa3 of the nanophotonic microlens array 160 may be formed such that maximum points s9, s10, s11, and s12 of the plurality of convex portions of the first nanophotonic microlens 161 are spaced apart from the center points c1, c2, c3, and c4 of the plurality of first photosensitive cells 111a, 111b, 111c, and 111d in the first direction (y-direction), and are distributed closer to the center line dcl of the first DTI structure d1 in the first direction (y-direction) than to the center points c1, c2, c3, and c4 of the plurality of first photosensitive cells 111a, 111b, 111c, and 111d.

As described above, unlike the maximum points s1, s2, s3, and s4 of the first nanophotonic microlens 131 of the nanophotonic microlens array 130 of FIGS. 7 and 8, the maximum points s9, s10, s11, and s12 of the first nanophotonic microlens 161 arranged in the peripheral regions aa2 and aa3 of the nanophotonic microlens array 160 may be distributed to be spaced apart from the center points c1, c2, c3, and c4 of the plurality of first photosensitive cells 111a, 111b, 111c, and 111d all in the first direction (y-direction).

Referring to FIGS. 25 to 29, the nanophotonic microlens array 160 may include the first nanophotonic microlens 161 and the fourth nanophotonic microlens 164 respectively corresponding to the first pixel 111 and the fourth pixel 114 that sense light of the first wavelength band, which is the green light region. The first and fourth nanophotonic microlenses 161 and 164 may correspond to the first filter 121 and the fourth filter 124, respectively. The first and fourth nanophotonic microlenses 161 and 164 may focus light on the first pixel 111 and the fourth pixel 114, respectively.

In addition, the nanophotonic microlens array 160 may include the second nanophotonic microlens 162 and the third nanophotonic microlens 163, which respectively correspond to the second pixel 112 that senses light of the second wavelength band, which is the blue light region, and the third pixel 113 that senses light of the third wavelength band, which is the red light region. The second nanophotonic microlens 162 may correspond to the second filter 122, and the third nanophotonic microlens 163 may correspond to the third filter 123. The second nanophotonic microlens 162 may focus light on the second pixel 112, and the third nanophotonic microlens 163 may focus light on the third pixel 113.

Here, each of the plurality of nanophotonic microlenses 161, 162, 163, and 164 may have a plurality of convex portions, which are more convex as the wavelength band of light sensed by the corresponding pixel is shorter. For example, as illustrated in FIG. 26, a plurality of second convex portions of the second nanophotonic microlens 162 corresponding to the second pixel 112 that senses light of the second wavelength band, which is the blue light region, may be formed to be more convex than a plurality of first convex portions of the first nanophotonic microlens 161 corresponding to the first pixel 111 that senses light of the first wavelength band, which is the green light region. In addition, as illustrated in FIG. 27, the plurality of first convex portions of the first nanophotonic microlens 161 corresponding to the first pixel 111 that senses light of the first wavelength band, which is the green light region, may be formed to be more convex than a plurality of third convex portions of the third nanophotonic microlens 163 corresponding to the third pixel 113 that senses light of the third wavelength band, which is the red light region. Furthermore, a plurality of fourth convex portions of the fourth nanophotonic microlens 164 corresponding to the fourth pixel 114 that senses light of the first wavelength band, which is the green light region, may have the same shape as that of the plurality of first convex portions of the first nanophotonic microlens 161.

Moreover, as illustrated in FIGS. 25 and 28, the plurality of convex portions of the first nanophotonic microlens 161 arranged in the peripheral regions aa2 and aa3 of the nanophotonic microlens array 160 may be symmetrically distributed in the second direction (x-direction) with respect to the center line dcl of the first DTI structure d1 in the first direction (y-direction). In addition, as illustrated in FIGS. 25, 28, and 29, the plurality of convex portions of the second to fourth nanophotonic microlenses 162, 163, and 164 arranged in the peripheral regions aa2 and aa3 of the nanophotonic microlens array 160 may be symmetrically distributed in the second direction (x-direction) with respect to the center lines of the second to fourth DTI structures d2, d3, and d4 in the first direction (y-direction), respectively.

In this case, as illustrated in FIG. 30, a plurality of second convex regions included in the phase profile of light transmitted through the second nanophotonic microlens 162 may be more convex than a plurality of first convex regions included in the phase profile of light transmitted through the first nanophotonic microlens 161. For example, the phase change of the light transmitted through the second nanophotonic microlens 162 may be substantially greater than the phase change of the light transmitted through the first nanophotonic microlens 161.

In addition, as illustrated in FIG. 31, a plurality of fourth convex regions included in the phase profile of light transmitted through the fourth nanophotonic microlens 164 may be more convex than a plurality of third convex regions included in the phase profile of light transmitted through the third nanophotonic microlens 163. For example, the phase change of the light transmitted through the fourth nanophotonic microlens 164 may be substantially greater than the phase change of the light transmitted through the third nanophotonic microlens 163.

In addition, as illustrated in FIG. 32, the plurality of first convex regions included in the phase profile of the light transmitted through the first nanophotonic microlens 161 may be more convex than the plurality of third convex regions included in the phase profile of the light transmitted through the third nanophotonic microlens 163.

In addition, as illustrated in FIG. 33, the plurality of second convex regions included in the phase profile of the light transmitted through the second nanophotonic microlens 162 may be more convex than the plurality of fourth convex regions included in the phase profile of the light transmitted through the fourth nanophotonic microlens 164.

Furthermore, the plurality of fourth convex regions included in the phase profile of the light transmitted through the fourth nanophotonic microlens 164 may have the same shape as the plurality of first convex regions included in the phase profile of the light transmitted through the first nanophotonic microlens 161.

Light incident on the left peripheral region aa2 among the peripheral regions aa2 and aa3 of the nanophotonic microlens array 160 is incident on the pixel array 1130 at an angle in the opposite direction to the direction of light incident on the right peripheral region aa3, with respect to the normal line of the pixel array 1130. Accordingly, the first to fourth nanophotonic microlenses 161 to 164 arranged in the left peripheral region aa2 of the nanophotonic microlens array 160 may have a shape inverted, in the first direction (y-direction), from the shape of the first to fourth nanophotonic microlens 161 to 164 arranged in the right peripheral region aa3.

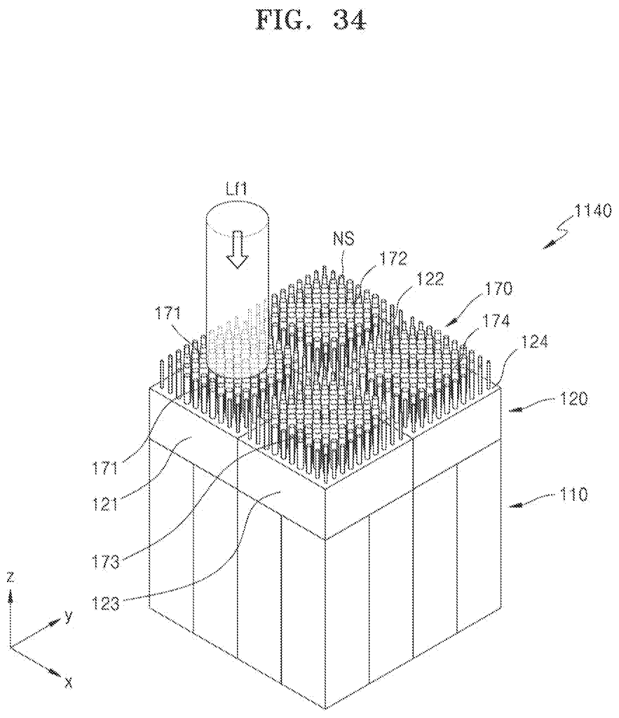

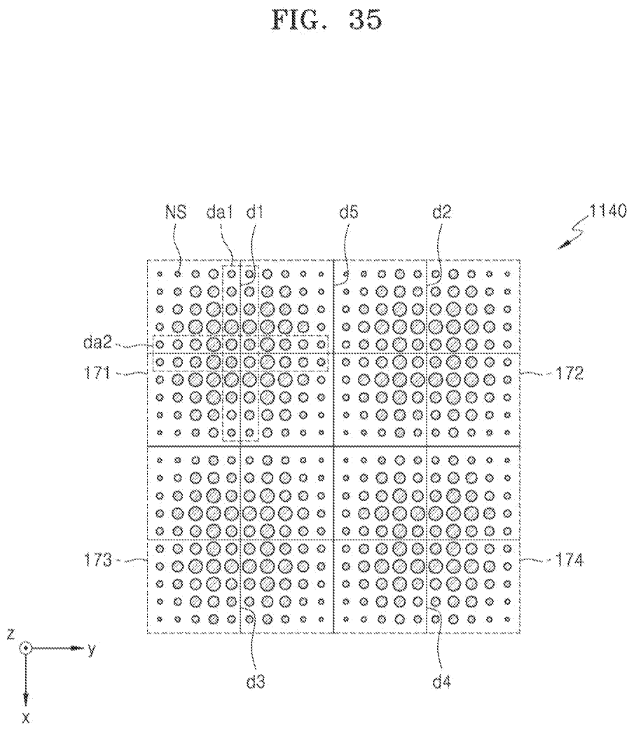

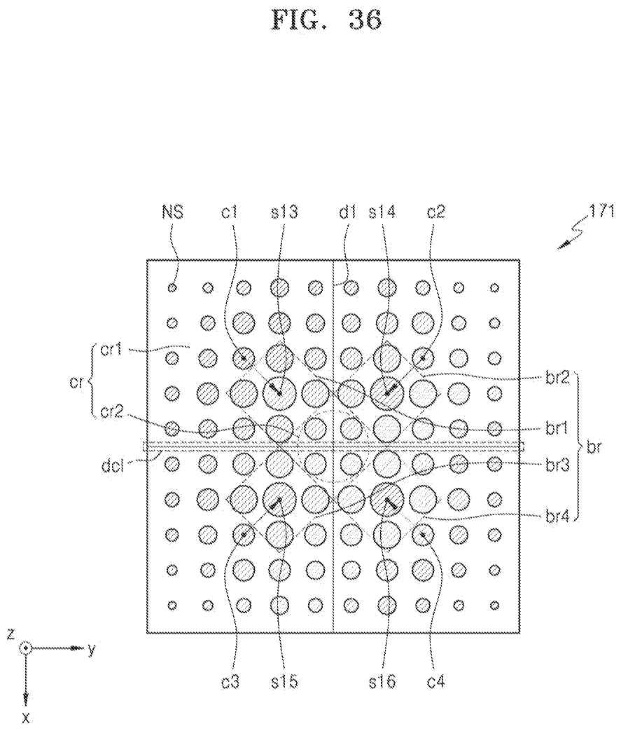

FIG. 34 is a perspective view illustrating an example configuration of a pixel array 1140 included in the optical sensor 1000, according to another example embodiment. FIG. 35 is a plan view illustrating an example configuration of the pixel array 1140 of FIG. 34. FIG. 36 is a plan view illustrating an example configuration of a first nanophotonic microlens 171 included in the pixel array 1140 of FIG. 34.

The pixel array 1140 of FIG. 34 may be substantially the same as the pixel array 1100 of FIG. 7, except that the configuration of a nanophotonic microlens array 170 is different from that of the nanophotonic microlens array 130 of FIG. 7. In FIG. 35, for convenience of description, the sensor substrate 110 and the filter layer 120 included in the pixel array 1140 are omitted. In describing FIGS. 34 to 36, descriptions that are provided in connection with FIGS. 1 to 15 are omitted. Also, in describing FIGS. 34 to 36, the reference numerals of the components illustrated in FIGS. 1 to 15 are used.

Hereinafter, characteristics of a plurality of nanophotonic microlenses 171, 172, 173, and 174 (hereinafter, also referred to as first to fourth nanophotonic microlenses 171 to 174) of the nanophotonic microlens array 170, which are distinguished from the configuration of the nanophotonic microlens array 130 of FIG. 7, will be described.

Referring to FIG. 35, the plurality of nanophotonic microlenses 171, 172, 173, and 174 may include a two-dimensional array of the first nanophotonic microlens 171 corresponding to the first pixel 111, the second nanophotonic microlens 172 corresponding to the second pixel 112, the third nanophotonic microlens 173 corresponding to the third pixel 113, and the fourth nanophotonic microlens 174 corresponding to the fourth pixel 114.

Each of the plurality of nanophotonic microlenses 171, 172, 173, and 174 may include a plurality of nanostructures NS arranged such that light transmitted through the nanophotonic microlens has a phase profile having a plurality of convex regions. The shapes, sizes (widths, heights), gaps, and arrangement of the plurality of nanostructures NS may be determined such that light immediately after passing through the first to fourth nanostructures 171 to 174 has a certain phase profile.

Although FIG. 35 illustrates that each of the plurality of nanophotonic microlenses 171, 172, 173, and 174 includes 100 nanostructures NS, the number of nanostructures NS may be less than or greater than 100. Light transmitted through the nanophotonic microlens array 170 may have substantially the same phase profile as that of the light transmitted through the nanophotonic microlens array 130 of FIG. 7 described above with reference to FIGS. 12 to 15.

For example, the light transmitted through the first nanophotonic microlens 171 may have a phase profile in which a plurality of convex regions overlap each other, and in this case, the number of convex regions included in the phase profile of the light transmitted through the first nanophotonic microlens 171 may be equal to the number of photosensitive cells 111a, 111b, 111c, and 111d included in the first pixel 111 corresponding to the first nanophotonic microlens 171. The plurality of convex regions in the phase profile of the light transmitted through the first nanophotonic microlens 171 may be regions distinguished from each other, and may be two-dimensionally arranged in the first direction (y-direction) and the second direction (x-direction).

Similarly, light transmitted through each of the second to fourth nanophotonic microlenses 172 to 174 may have a phase profile in which a plurality of convex regions overlap each other. In this case, the number of convex regions in the phase profile of the light transmitted through each of the second to fourth nanophotonic microlenses 172 to 174 may be equal to the number of photosensitive cells, i.e., the number of second photosensitive cells 112a, 112b, 112c, and 112d, the number of third photosensitive cells 113a, 113b, 113c, and 113d, or the number of fourth photosensitive cells 114a, 114b, 114c, and 114d, included in the pixel 112, 113, or 114 corresponding to the nanophotonic microlens.

The plurality of nanostructures NS included in each of the plurality of nanophotonic microlenses 171, 172, 173, and 174 may be two-dimensionally arranged in the first direction (y-direction) and the second direction (x-direction). For example, each of the plurality of nanophotonic microlenses 171, 172, 173, and 174 may include a plurality of rows in the first direction (y) and a plurality of columns in the second direction (x), in which the plurality of nanostructures NS are provided.

Any one row in each of the plurality of nanophotonic microlenses 171, 172, 173, and 174 may include a plurality of nanostructures NS, the diameters of which increase, decrease, increase, and decrease in the first direction (y-direction). In this case, gaps between the plurality of nanostructures NS included in each of the plurality of nanophotonic microlenses 171, 172, 173, and 174 in the first direction (y-direction) may be constant. In addition, the nanostructure NS located at the center of any one row in each of the plurality of nanophotonic microlenses 171, 172, 173, and 174 may have a diameter smaller than that of the nanostructures NS adjacent to both sides thereof in the first direction (y-direction). For example, the diameters of the nanostructures NS provided in a 1-1st DTI region da1 including a region corresponding to the first DTI structure d1, in any row of the first nanophotonic microlens 171 may be smaller than the diameters of the nanostructures NS provided in a peripheral region of the 1-1st DTI region da1 in the first direction (y-direction).

In addition, any one column in each of the plurality of nanophotonic microlenses 171, 172, 173, and 174 may include a plurality of nanostructures NS, the diameters of which increase, decrease, increase, and decrease in the second direction (x-direction). In this case, gaps between the plurality of nanostructures NS included in each of the plurality of nanophotonic microlenses 171, 172, 173, and 174 in the second direction (x-direction) may be constant. The gaps between the plurality of nanostructures NS included in each of the plurality of nanophotonic microlenses 171, 172, 173, and 174 in the second direction (x-direction) may be equal to the gaps in the first direction (y-direction). In addition, the nanostructure NS located at the center of any one column in each of the plurality of nanophotonic microlenses 171, 172, 173, and 174 may have a diameter smaller than that of the nanostructures NS adjacent to both sides thereof in the second direction (x-direction). For example, the diameters of the nanostructures NS provided in a 1-2nd DTI region da2 including a region corresponding to the first DTI structure d1, in any column of the first nanophotonic microlens 171 may be smaller than the diameters of the nanostructures NS provided in a peripheral region of the 1-2nd DTI region da2 in the second direction (x-direction).

The arrangement of the plurality of nanostructures NS included in the first nanophotonic microlens 171 described above may be substantially equally applied to the second to fourth nanophotonic microlenses 172 to 174.

In addition, each of the plurality of nanophotonic microlenses 171, 172, 173, and 174 may include a sparse area in which a plurality of nanostructures NS having relatively small diameters are distributed, and a dense area in which a plurality of nanostructures NS having relatively large diameters are distributed. The dense area included in each of the plurality of nanophotonic microlenses 171, 172, 173, and 174 may be surrounded by the sparse area.

For example, referring to FIG. 36, the first nanophotonic microlens 171 may include a dense area br surrounded by a sparse area cr. In this case, the dense area br may include a plurality of sub-dense areas br1, br2, br3, and br4 (hereinafter, also referred to as first to fourth sub-dense areas br1 to br4) spaced apart from each other by the sparse area cr. In each of the plurality of sub-dense areas br1, br2, br3, and br4, the plurality of nanostructures NS may be arranged such that the diameters thereof increases toward the center from an edge of the sub-dense area. In this case, the sub-dense areas br1, br2, br3, and br4 may be surrounded by a first sparse area cr1. In addition, the plurality of sub-dense areas br1, br2, br3, and br4 may be arranged to surround a second sparse area cr2. The first sparse area cr1 may surround the plurality of sub-dense areas br1, br2, br3, and br4, and may occupy a wider region than the second sparse area cr2 surrounded by the plurality of sub-dense areas br1, br2, br3, and br4. As described above, the sparse area cr may be formed to correspond to the center and edge portions of the first nanophotonic microlens 171. In addition, the plurality of sub-dense areas br1, br2, br3, and br4 may be symmetrically distributed with respect to a region corresponding to the first DTI structure d1 of the first nanophotonic microlens 171.

In addition, center points s13, s14, s15, and s16 of the plurality of sub-dense areas br1, br2, br3, and br4 may be provided in regions between the first DTI structure d1 of the first nanophotonic microlens 171 and the center points c1, c2, c3, and c4 of the plurality of first photosensitive cells 111a, 111b, 111c, and 111d. Accordingly, the center points s13, s14, s15, and s16 of the plurality of sub-dense areas br1, br2, br3, and br4 may be closer to the center of the first nanophotonic microlens 171 than to the center points c1, c2, c3, and c4 of the first photosensitive cells 111a, 111b, 111c, and 111d.

The description regarding the dense area br and the sparse area cr of the first nanophotonic microlens 171 may be substantially equally applied to the second to fourth nanophotonic microlenses 172, 173, and 174.

The number of sub-dense areas included in each of the plurality of nanophotonic microlenses 171, 172, 173, and 174 may be equal to the number of photosensitive cells included in the pixel corresponding to each of the plurality of nanophotonic microlenses 171, 172, 173, and 174.

For example, the first nanophotonic microlens 171 may include the plurality of sub-dense areas br1, br2, br3, and br4, the number of which is equal to the number of first photosensitive cells 111a, 111b, 111c, and 111d included in the first pixel 111. In this case, the first pixel 111 may include four first photosensitive cells 111a, 111b, 111c, and 111d, and the first nanophotonic microlens 171 may include the first sub-dense area br1, the second sub-dense area br2, the third sub-dense area br3, and the fourth sub-dense area br4 corresponding thereto.

The description regarding the number of sub-dense areas br1, br2, br3, and br4 of the first nanophotonic microlens 171 may be substantially equally applied to the second to fourth nanophotonic microlenses 172, 173, and 174.

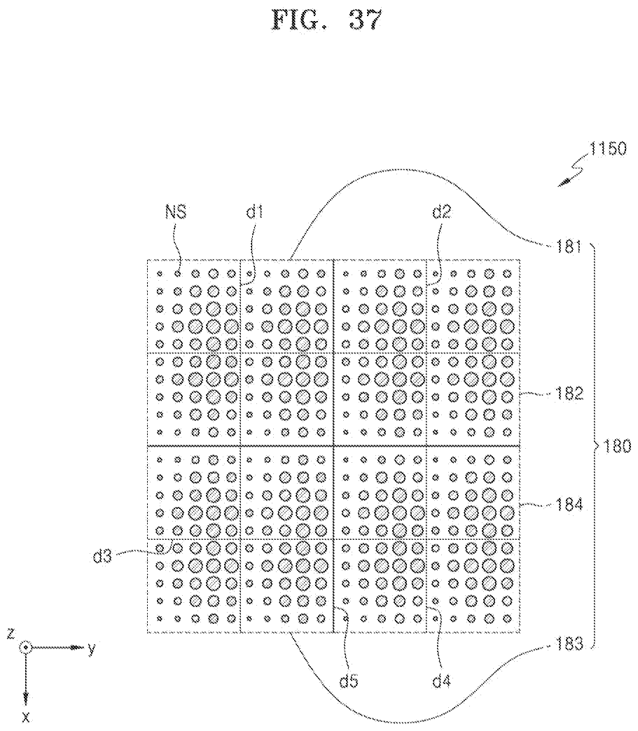

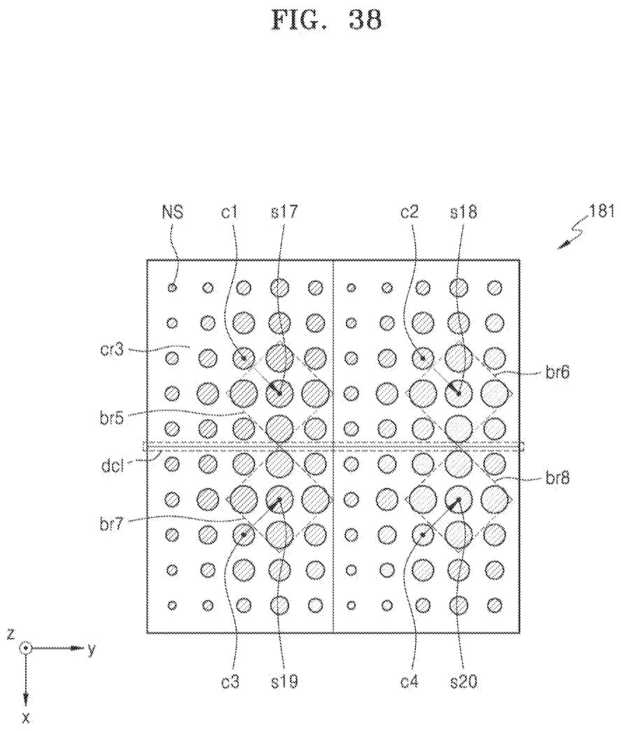

FIG. 37 is a plan view illustrating an example configuration of a pixel array 1150 included in the optical sensor 1000, according to another example embodiment. FIG. 38 is a plan view illustrating an example configuration of a first nanophotonic microlens 181 included in the pixel array 1150 of FIG. 34.

The pixel array 1150 of FIG. 37 may be substantially the same as the pixel array 1140 of FIG. 34, except that the configuration of a nanophotonic microlens array 180 is different from that of the nanophotonic microlens array 170 of FIG. 34. In FIG. 37, for convenience of description, the sensor substrate 110 and the filter layer 120 included in the pixel array 1150 are omitted. In describing FIG. 37, descriptions that are provided in connection with FIGS. 1 to 15 and 34 to 36 will be omitted. Also, in describing FIG. 37, the reference numerals of the components illustrated in FIGS. 1 to 15 are used.

The configuration of the central region aa1 (see FIG. 6) of the nanophotonic microlens array 180 included in the pixel array 1150 of FIG. 37 may be the same as that of the nanophotonic microlens array 170 included in the pixel array 1140 of FIG. 34.

According to another example embodiment, the configuration of the peripheral regions aa2 and aa3 (see FIG. 6) of the nanophotonic microlens array 180 may be different from that of the nanophotonic microlens array 170. However, the nanophotonic microlens array 180 may be substantially the same as the nanophotonic microlens array 170 of FIG. 34 in that each of a plurality of nanophotonic microlenses 181, 182, 183, and 184 (hereinafter, also referred to as first to fourth nanophotonic microlenses 181 to 184) arranged in the peripheral regions aa2 and aa3 of the nanophotonic microlens array 180 includes the plurality of nanostructures NS arranged such that light transmitted through each of the plurality of nanophotonic microlenses 181, 182, 183, and 184 has a phase profile having a plurality of convex regions. Also, the nanophotonic microlens array 170 of FIG. 34 may be substantially the same as the nanophotonic microlens array 170 of FIG. 34 in that each of the plurality of nanophotonic microlenses 181, 182, 183, and 184 arranged in the peripheral regions aa2 and aa3 of the nanophotonic microlens array 180 includes a dense area and a sparse area, and a plurality of sub-dense areas included in the dense area are surrounded by the sparse area.

Hereinafter, characteristics of the plurality of nanophotonic microlenses 181, 182, 183, and 184 arranged in the peripheral regions aa2 and aa3 of the nanophotonic microlens array 180, which are distinguished from the configuration of the nanophotonic microlens array 170 of FIG. 34, will be described.

Referring to FIG. 37, each of the plurality of nanophotonic microlenses 181, 182, 183, and 184 arranged in the peripheral regions aa2 and aa3 of the nanophotonic microlens array 180 may be formed such that the center points of the plurality of sub-dense areas of each of the plurality of nanophotonic microlenses 181, 182, 183, and 184 are spaced apart from the respective center points of the plurality of photosensitive cells, i.e., the plurality of first photosensitive cells 111a, 111b, 111c, and 111d, the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d, in the first direction (y-direction), and are distributed to be closer to the center line of the DTI structure in the first direction (y-direction) than to each of the center points of first photosensitive cells 111a, 111b, 111c, and 111d, the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d.

For example, referring to FIG. 38, the first nanophotonic microlens 181 arranged in the peripheral regions aa2 and aa3 of the nanophotonic microlens array 180 may be formed such that center points s17, s18, s19, and s20 of a plurality of sub-dense areas br5, br6, br7, and br8, which are spaced apart from each other by a sparse area cr3 of the first nanophotonic microlens 181, are spaced apart from the center points c1, c2, c3, and c4 of the plurality of first photosensitive cells 111a, 111b, 111c, and 111d in the first direction (y-direction), and are distributed to be closer to the center line dcl of the first DTI structure d1 in the first direction (y-direction) than to the center points c1, c2, c3, and c4 of the plurality of first photosensitive cells 111a, 111b, 111c, and 111d.

As described above, unlike the center points s13, s14, s15, and s16 of the plurality of sub-dense areas br5, br6, br7, and br8 of the first nanophotonic microlens 171 of FIG. 36, the center points s17, s18, s19, and s20 of the plurality of sub-dense regions br5, br6, br7, and br8 of the first nanophotonic microlens 181 arranged in the peripheral regions aa2 and aa3 of the nanophotonic microlens array 180 may be distributed to be spaced apart from the center points c1, c2, c3, and c4 of the plurality of first photosensitive cells 111a, 111b, 111c, and 111d in the first direction (y-direction).

As illustrated in FIG. 38, the center points s17, s18, s19, and s20 of the plurality of sub-dense areas br5, br6, br7, and br8 of the first nanophotonic microlens 181 arranged in the peripheral regions aa2 and aa3 of the nanophotonic microlens array 180 may be symmetrically distributed in the second direction (x-direction) with respect to the center line dcl of the first DTI structure d1 in the first direction (y-direction). In this case, the phase profile, in the second direction (x-direction), of light transmitted through the first nanophotonic microlens 181, which includes the center points s17, s18, s19, and s20 of the plurality of sub-dense areas br5, br6, br7, and br8 symmetrically arranged in the second direction (x-direction), and is arranged in the peripheral regions aa2 and aa3 of the nanophotonic microlens array 180, may be the same as illustrated in FIG. 13.

In addition, as the distance between the central region aa1 of the nanophotonic microlens array 180 and the first nanophotonic microlens 181 increases, the distances between the center points s17, s18, s19, and s20 of the plurality of sub-dense areas and the center points c1, c2, c3, and c4 of the plurality of first photosensitive cells 111a, 111b, 111c, and 111d in the first direction (y-direction) may also increase. For example, the nanophotonic microlens array 180 may include a 1-1st nanophotonic microlens arranged at one point in the peripheral regions aa2 and aa3, and a 1-2nd nanophotonic microlens arranged farther from the central region aa1 than the 1-1st nanophotonic microlens. In this case, the distance between the center points of the plurality of sub-dense areas and the center points of the plurality of photosensitive cells in the 1-2nd nanophotonic microlens may be greater than the distance between the center points of the plurality of sub-dense areas and the center points of the plurality of photosensitive cells in the 1-1st nanophotonic microlens. Accordingly, despite the fact that the CRA of incident light increases toward the edge of the nanophotonic microlens array 180, the phase change of the incident light may also increase to that extent, and consequently, the difference between the amount of light collected on the plurality of photosensitive cells arranged in the peripheral regions aa2 and aa3 of the nanophotonic microlens array 180 and the amount of light collected on the plurality of photosensitive cells arranged in the central region aa1 may be minimized.

Similarly, each of the second to fourth nanophotonic microlenses 182 to 184 arranged in the peripheral regions aa2 and aa3 of the nanophotonic microlens array 180 may be formed such that the center points of the plurality of sub-dense areas, which are spaced apart from each other by the sparse area of the nanophotonic microlens, are spaced apart from the center points of the plurality of second photosensitive cells 112a, 112b, 112c, and 112d, the plurality of third photosensitive cells 113a, 113b, 113c, and 113d, or the plurality of fourth photosensitive cells 114a, 114b, 114c, and 114d, in the first direction (y-direction), and are distributed to be closer to the center line of the second, third, or fourth DTI structure d2, d3, or d4 in the first direction (y-direction) than to the center points of the plurality of corresponding photosensitive cells.

In addition, the plurality of convex portions of the second to fourth nanophotonic microlenses 182 to 184 arranged in the peripheral regions aa2 and aa3 of the nanophotonic microlens array 180 may be symmetrically distributed in the second direction (x-direction) with respect to the center lines of the second to fourth DTI structures d2 to d4 in the first direction (y-direction), respectively.

Light transmitted through the nanophotonic microlens array 180 may have substantially the same phase profile as that of the light transmitted through the nanophotonic microlens array 140 described above with reference to FIGS. 16 to 19.

Also, light incident on the left peripheral region aa2 among the peripheral regions aa2 and aa3 of the nanophotonic microlens array 180 is incident on the pixel array 1150 at an angle in the opposite direction to the direction of light incident on the right peripheral region aa3, with respect to the normal line of the pixel array 1150. Accordingly, the first to fourth nanophotonic microlenses 181 to 184 arranged in the left peripheral region aa2 of the nanophotonic microlens array 180 may have a shape inverted, in the first direction (y-direction), from the shape of the first to fourth nanophotonic microlens 181 to 184 arranged in the right peripheral region aa3.

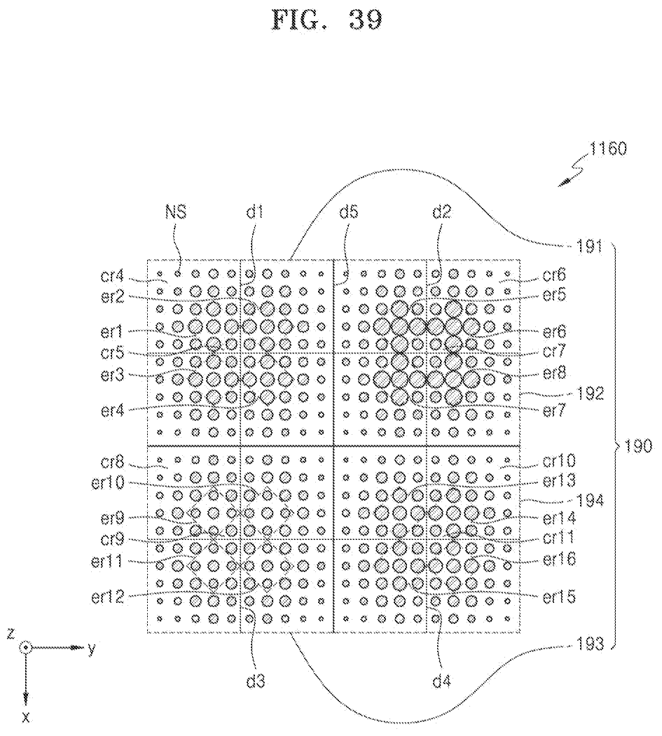

FIG. 39 is a plan view illustrating an example configuration of a pixel array 1160 included in the optical sensor 1000, according to another example embodiment.

The pixel array 1160 of FIG. 39 may be substantially the same as the pixel array 1140 of FIG. 34, except that a plurality of nanophotonic microlenses 191, 192, 193, and 194 (hereinafter, also referred to as first to fourth nanophotonic microlenses 191 to 194) included in a nanophotonic microlens array 190 have different shapes according to wavelengths of light sensed by corresponding pixels, unlike the nanophotonic microlens array 170 of FIG. 34. In FIG. 39, for convenience of description, the sensor substrate 110 and the filter layer 120 included in the pixel array 1160 are omitted. In describing FIG. 39, descriptions that are provided in connection with FIGS. 1 to 15 and 34 to 36 will be omitted. Also, in describing FIG. 39, the reference numerals of the components illustrated in FIGS. 1 to 15 are used.

Referring to FIG. 39, the nanophotonic microlens array 190 may include the first nanophotonic microlens 191 and the fourth nanophotonic microlens 194 respectively corresponding to the first pixel 111 and the fourth pixel 114 that sense light of the first wavelength band, which is the green light region. The first and fourth nanophotonic microlenses 191 and 194 may correspond to the first filter 121 and the fourth filter 124, respectively. The first and fourth nanophotonic microlenses 191 and 194 may focus light on the first pixel 111 and the fourth pixel 114, respectively.

In addition, the nanophotonic microlens array 190 may include the second nanophotonic microlens 192 corresponding to the second pixel 112 that senses light of the second wavelength band, which is the blue light region. The second nanophotonic microlens 192 may correspond to the second filter 122. The second nanophotonic microlens 192 may focus light on the second pixel 112.

Furthermore, the nanophotonic microlens array 190 may include the third nanophotonic microlens 193 corresponding to the third pixel 113 that senses light of the third wavelength band, which is the red light region. The third nanophotonic microlens 193 may correspond to the third filter 123. The third nanophotonic microlens 193 may focus light on the third pixel 113.

Here, the plurality of nanophotonic microlenses 191, 192, 193, and 194 may include a plurality of sub-dense areas having the plurality of nanostructures NS, the density of which increases as the wavelength band of light sensed by the corresponding pixel decreases. In this case, the average diameter of the plurality of nanostructures NS included in the plurality of sub-dense areas having relatively high density may be greater than the average diameter of the plurality of nanostructures NS included in the plurality of sub-dense areas having relatively low density.

For example, as illustrated in FIG. 39, the average diameter of the plurality of nanostructures NS included in a plurality of second sub-dense areas er5, er6, er7, and er8, which are spaced apart from each other by second sparse areas cr6 and cr7 of the second nanophotonic microlens 192 corresponding to the second pixel 112 that senses light of the second wavelength band, which is the blue light region, may be greater than the average diameter of the plurality of nanostructures NS included in a plurality of first sub-dense areas er1, er2, er3, and er4, which are spaced apart from each other by first sparse areas cr4 and cr5 of the first nanophotonic microlens 191 corresponding to the first pixel 111 that senses light of the first wavelength band, which is the green light region. In addition, the average diameter of the plurality of nanostructures NS included in the plurality of first sub-dense areas er1, er2, er3, and er4, which are spaced apart from each other by the first sparse areas cr4 and cr5 of the first nanophotonic microlens 191 corresponding to the first pixel 111 that senses light of the first wavelength band, which is the green light region, may be greater than the average diameter of the plurality of nanostructures NS included in a plurality of third sub-dense areas er9, er10, er11, and er12, which are spaced apart from each other by third sparse areas cr8 and cr9 of the third nanophotonic microlens 193 corresponding to the third pixel 113 that senses light of the third wavelength band, which is the red light region. Furthermore, the average diameter of the plurality of nanostructures NS included in a plurality of fourth sub-dense areas er13, er14, er15, and er16, which are spaced apart from each other by fourth sparse areas cr10 and cr11 of the fourth nanophotonic microlens 194 corresponding to the fourth pixel 114 that senses light of the first wavelength band, which is the green light region, may be equal to the average diameter of the plurality of nanostructures NS included in the plurality of first sub-dense areas er1, er2, er3, and er4, which are spaced apart from each other by the first sparse areas cr4 and cr5 of the first nanophotonic microlens 191.

Light transmitted through the nanophotonic microlens array 190 may have substantially the same phase profile as that of the light transmitted through the nanophotonic microlens array 150 described above with reference to FIGS. 20 to 24.

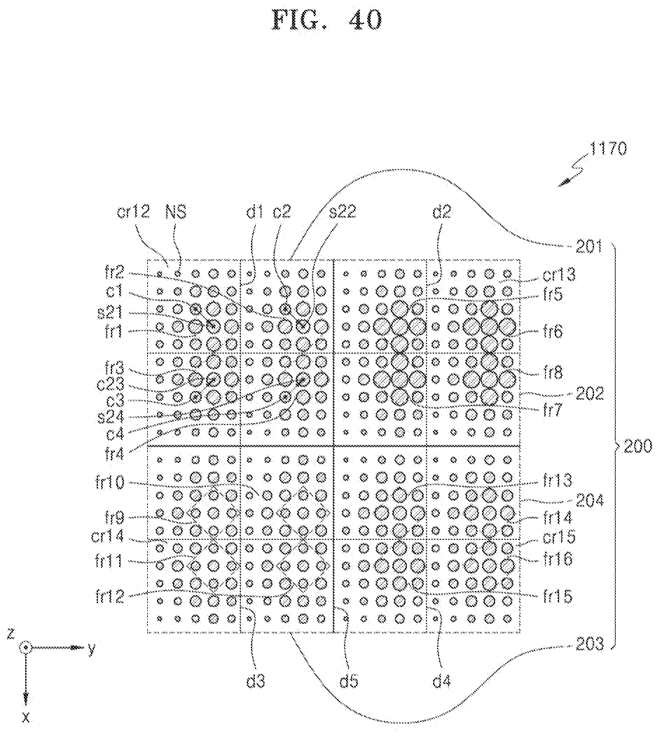

FIG. 40 is a plan view schematically illustrating an example configuration of a pixel array 1170 included in the optical sensor 1000, according to another example embodiment.

The pixel array 1170 of FIG. 40 may be substantially the same as the pixel array 1150 of FIG. 37, except that a plurality of nanophotonic microlenses 201, 202, 203, and 204 (hereinafter, also referred to as first to fourth nanophotonic microlenses 201 to 204) included in a nanophotonic microlens array 200 have different shapes according to wavelengths of light sensed by corresponding pixels, unlike the nanophotonic microlens array 180 of FIG. 37. In FIG. 40, for convenience of description, the sensor substrate 110 and the filter layer 120 included in the pixel array 1170 are omitted. In describing FIG. 40, descriptions that are provided in connection with FIGS. 1 to 15 and 34 to 38 will be omitted. Also, in describing FIG. 40, the reference numerals of the components illustrated in FIGS. 1 to 15 are used.

Referring to FIG. 40, each of the plurality of nanophotonic microlenses 201, 202, 203, and 204 arranged in the peripheral regions aa2 and aa3 of the nanophotonic microlens array 200 may be formed such that the center points of corresponding ones of a plurality of sub-dense areas fr1, fr2, fr3, fr4, fr5, fr6, fr7, fr8, fr9, fr10, fr11, fr12, fr13, fr14, fr15, and fr16, which are spaced apart from each other by a sparse area cr12, cr13, cr14, or cr15 of the nanophotonic microlens, are spaced apart from the center points of corresponding ones of the plurality of photosensitive cells 111a, 111b, 111c, 111d, 112a, 112b, 112c, 112d, 113a, 113b, 113c, 113d, 114a, 114b, 114c, and 114d in the first direction (y-direction), respectively, and are distributed to be closer to the center line of the DTI structure in the first direction (y-direction) than to each of the center points of corresponding ones of the plurality of photosensitive cells 111a, 111b, 111c, 111d, 112a, 112b, 112c, 112d, 113a, 113b, 113c, 113d, 114a, 114b, 114c, and 114d.

For example, referring to FIG. 40, the first nanophotonic microlens 201 arranged in the peripheral regions aa2 and aa3 of the nanophotonic microlens array 200 may be formed such that center points s21, s22, s23, and s24 of a plurality of first sub-dense areas fr1, fr2, fr3, and fr4, which are spaced apart from each other by a first sparse area cr12 of the first nanophotonic microlens 201, are spaced apart from the center points c1, c2, c3, and c4 of the plurality of first photosensitive cells 111a, 111b, 111c, and 111d in the first direction (y-direction), and are distributed to be closer to the center line dcl of the first DTI structure d1 in the first direction (y-direction) than to the center points c1, c2, c3, and c4 of the plurality of first photosensitive cells 111a, 111b, 111c, and 111d.

As described above, the center points s21, s22, s23, and s24 of the plurality of first sub-dense areas fr1, fr2, fr3, and fr4 of the first nanophotonic microlens 201 arranged in the peripheral regions aa2 and aa3 of the nanophotonic microlens array 200 may be distributed to be spaced apart from the center points c1, c2, c3, and c4 of the plurality of first photosensitive cells 111a, 111b, 111c, and 111d in the first direction (y-direction).

As illustrated in FIG. 40, the center points s21, s22, s23, and s24 of the plurality of first sub-dense areas fr1, fr2, fr3, and fr4 of the first nanophotonic microlens 201 arranged in the peripheral regions aa2 and aa3 of the nanophotonic microlens array 200 may be symmetrically distributed in the second direction (x-direction) with respect to the center line dcl of the first DTI structure d1 in the first direction (y-direction).

The description regarding the number of first sub-dense areas fr1, fr2, fr3, and fr4 of the first nanophotonic microlens 201 may be substantially equally applied to the second to fourth nanophotonic microlenses 202, 203, and 204.

In addition, the nanophotonic microlens array 200 may include the first nanophotonic microlens 201 and the fourth nanophotonic microlens 204 respectively corresponding to the first pixel 111 and the fourth pixel 114 that sense light of the first wavelength band, which is the green light region. The first and fourth nanophotonic microlenses 201 and 204 may correspond to the first filter 121 and the fourth filter 124, respectively. The first and fourth nanophotonic microlenses 201 and 204 may focus light on the first pixel 111 and the fourth pixel 114, respectively.

In addition, the nanophotonic microlens array 200 may include the second nanophotonic microlens 202 corresponding to the second pixel 112 that senses light of the second wavelength band, which is the blue light region. The second nanophotonic microlens 202 may correspond to the second filter 122. The second nanophotonic microlens 202 may focus light on the second pixel 112.

Furthermore, the nanophotonic microlens array 200 may include the third nanophotonic microlens 203 corresponding to the third pixel 113 that senses light of the third wavelength band, which is the red light region. The third nanophotonic microlens 203 may correspond to the third filter 123. The third nanophotonic microlens 203 may focus light on the third pixel 113.

Here, the plurality of nanophotonic microlenses 201, 202, 203, and 204 may include a plurality of sub-dense areas having the plurality of nanostructures NS, the density of which increases as the wavelength band of light sensed by the corresponding pixel decreases. In this case, the average diameter of the plurality of nanostructures NS included in the plurality of sub-dense areas having relatively high density may be greater than the average diameter of the plurality of nanostructures NS included in the plurality of sub-dense areas having relatively low density.

For example, as illustrated in FIG. 40, the average diameter of the plurality of nanostructures NS included in a plurality of second sub-dense areas fr5, fr6, fr7, and fr8 of the second nanophotonic microlens 202 corresponding to the second pixel 112 that senses light of the second wavelength band, which is the blue light region, may be greater than the average diameter of the plurality of nanostructures NS included in the plurality of first sub-dense areas fr1, fr2, fr3, and fr4 of the first nanophotonic microlens 201 corresponding to the first pixel 111 that senses light of the first wavelength band, which is the green light region. In addition, the average diameter of the plurality of nanostructures NS included in the plurality of first sub-dense areas fr1, fr2, fr3, and fr4 of the first nanophotonic microlens 201 corresponding to the first pixel 111 that senses light of the first wavelength band, which is the green light region, may be greater than the average diameter of the plurality of nanostructures NS included in a plurality of third sub-dense areas fr9, fr10, fr11, and fr12 of the third nanophotonic microlens 203 corresponding to the third pixel 113 that senses light of the third wavelength band, which is the red light region. Furthermore, the average diameter of the plurality of nanostructures NS included in a plurality of fourth sub-dense areas fr13, fr14, fr15, and fr16 of the fourth nanophotonic microlens 204 corresponding to the fourth pixel 114 that senses light of the first wavelength band, which is the green light region, may be equal to the average diameter of the plurality of nanostructures NS included in the plurality of first sub-dense areas fr1, fr2, fr3, and fr4 of the first nanophotonic microlens 201.

Light transmitted through the nanophotonic microlens array 200 may have substantially the same phase profile as that of the light transmitted through the nanophotonic microlens array 160 described above with reference to FIGS. 25 to 33.

Light incident on the left peripheral region aa2 among the peripheral regions aa2 and aa3 of the nanophotonic microlens array 200 is incident on the pixel array 1170 at an angle in the opposite direction to the direction of light incident on the right peripheral region aa3, with respect to the normal line of the pixel array 1170. Accordingly, the first to fourth nanophotonic microlenses 201 to 204 arranged in the left peripheral region aa2 of the nanophotonic microlens array 200 may have a shape inverted, in the first direction (y-direction), from the shape of the first to fourth nanophotonic microlens 201 to 204 arranged in the right peripheral region aa3.

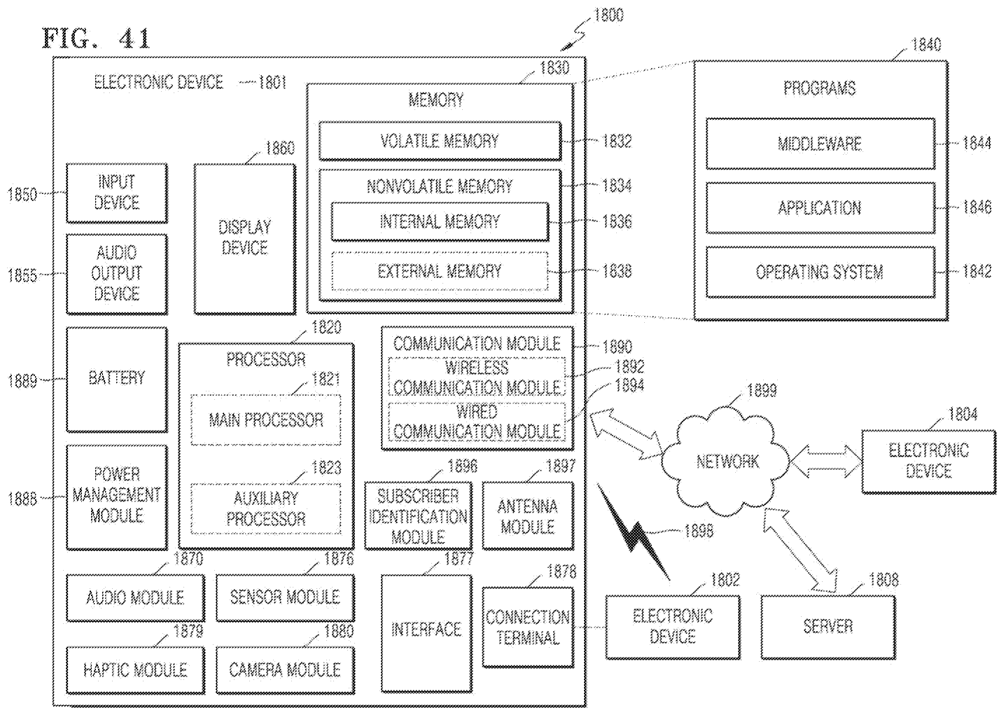

FIG. 41 is a block diagram illustrating an electronic device 1801 including an image sensor, according to an example embodiment.

Referring to FIG. 41, in a network environment 1899, the electronic device 1801 may communicate with another electronic device 1802 through a first network 1898 (e.g., a short-range wireless communication network) or may communicate with another electronic device 1804 and/or a server 1808 through a second network 1899 (e.g., a long-range wireless communication network). The electronic device 1801 may communicate with the electronic device 1804 through the server 1808. The electronic device 1801 may include a processor 1820, a memory 1830, an input device 1850, an audio output device 1855, a display device 1860, an audio module 1870, a sensor module 1876, an interface 1877, a haptic module 1879, the camera module 1880, a power management module 1888, a battery 1889, a communication module 1890, a subscriber identification module 1896, and/or an antenna module 1897. Some (e.g., the display device 1860) of these components may be omitted or other components may be additionally included in the electronic device 1801. Some of these components may be implemented in one integrated circuit. For example, the sensor module 1876 (e.g., a fingerprint sensor, an iris sensor, an illuminance sensor) may be embedded in the display device 1860 (e.g., a display) to be implemented.

The processor 1820 may execute software (e.g., programs 1840) to control one or more other components (e.g., hardware or software components) of the electronic device 1801 connected to the processor 1820, and may perform a variety of data processing or operations. As part of the data processing or operations, the processor 1820 may load commands and/or data received from other components (e.g., the sensor module 1876, the communication module 1890) into a volatile memory 1832, process the commands and/or data stored in the volatile memory 1832, and store result data in a nonvolatile memory 1834. The processor 1820 may include a main processor 1821 (e.g., a central processing unit, an application processor) and an auxiliary processor 1823 (e.g., a graphics processing unit, an image signal processor, a sensor hub processor, a communication processor) that may operate independently of or together with the main processor 1821. The auxiliary processor 1823 may consume less power than the main processor 1821, and may perform a specialized function.

The auxiliary processor 1823 may control functions and/or states related to some components (e.g., the display device 1860, the sensor module 1876, the communication module 1890) of the electronic device 1801, on behalf of the main processor 1821 while the main processor 1821 is in an inactive (e.g., sleep) state, or with the main processor 1821 while the main processor 1821 is in an active (e.g., application execution) state. The auxiliary processor 1823 (e.g., an image signal processor, a communication processor) may be implemented as part of other functionally relevant components (e.g., the camera module 1880, the communication module 1890).

The memory 1830 may store a variety of data required by components (e.g., the processor 1820, the sensor module 1876) of the electronic device 1801. The data may include, for example, software (e.g., programs 1840, etc.) and input data and/or output data for commands related thereto. The memory 1830 may include the volatile memory 1832 and/or the nonvolatile memory 1834.

The programs 1840 may be stored as software in the memory 1830, and may include an operating system 1842, middleware 1844, and/or an application 1846.

The input device 1850 may receive commands and/or data to be used for the components (e.g., the processor 1820) of the electronic device 1801 from the outside (e.g., a user) of the electronic device 1801. The input device 1850 may include a remote controller, a microphone, a mouse, a keyboard, and/or a digital pen (e.g., a stylus pen).

The audio output device 1855 may output an audio signal to the outside of the electronic device 1801. The audio output device 1855 may include a speaker and/or a receiver. The speaker may be used for general purposes such as multimedia playback or recording playback, and the receiver may be used to receive an incoming call. The receiver may be combined as part of the speaker or may be implemented as an independent separate device.

The display device 1860 may visually provide information to the outside of the electronic device 1801. The display device 1860 may include a display, a hologram device, or a projector, and a control circuit for controlling the devices. The display device 1860 may include a touch circuitry configured to detect a touch or a sensor circuitry (e.g., a pressure sensor) configured to measure a strength of a force generated by the touch.

The audio module 1870 may convert a sound into an electrical signal or vice versa. The audio module 1870 may obtain a sound through the input device 1850 or may output the sound through the audio output device 1855 and/or a speaker and/or headphones of another electronic device (e.g., the electronic device 1802) directly or wirelessly connected to the electronic device 1801.

The sensor module 1876 may detect an operating state (e.g., power, temperature) of the electronic device 1801 or an external environment state (e.g., a user state), and may generate an electrical signal and/or a data value corresponding to the detected state. The sensor module 1876 may include a gesture sensor, a gyro sensor, a barometric sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 1877 may support one or more designated protocols, which may be used to directly or wirelessly connect the electronic device 1801 to another electronic device (e.g., the electronic device 1802). The interface 1877 may include a high-definition multimedia interface (HDMI), a universal serial bus (USB) interface, a secure digital (SD) card interface, and/or an audio interface.

A connection terminal 1878 may include a connector through which the electronic device 1801 may be physically connected to another electronic device (e.g., the electronic device 1802). The connection terminal 1878 may include an HDMI connector, a USB connector, an SD card connector, and/or an audio connector (e.g., a headphone connector).

The haptic module 1879 may convert an electrical signal into a mechanical stimulus (e.g., vibration, movement, etc.) or an electrical stimulus that a user may perceive through a tactile or motor sensations. The haptic module 1879 may include a motor, a piezoelectric element, and/or an electrical stimulation device.

The camera module 1880 may capture a still image or a moving image. The camera module 1880 may include a lens assembly including one or more lenses, image sensors, image signal processors, and/or flashes. A lens assembly included in the camera module 1880 may collect light emitted from an object to be image-captured.

The power management module 1888 may manage power supplied to the electronic device 1801. The power management module 1888 may be implemented as part of a power management integrated circuit (PMIC).

The battery 1889 may supply power to components of the electronic device 1801. The battery 1889 may include a non-rechargeable primary cell, a rechargeable secondary cell, and/or a fuel cell.

The communication module 1890 may support establishment a direct (wired) communication channel and/or a wireless communication channel between the electronic device 1801 and other electronic devices (e.g., the electronic devices 1802 and 1804, the server 1808) and communication through the established communication channel. The communication module 1890 may operate independently of the processor 1820 (e.g., an application processor), and may include one or more communication processors supporting direct communication and/or wireless communication. The communication module 1890 may include a wireless communication module 1892 (e.g., a cellular communication module, a short-range wireless communication module, a global navigation satellite system (GNSS) communication module) and/or a wired communication module 1894 (e.g., a local area network (LAN) communication module, a power line communication module). The corresponding communication module among these communication modules may communicate with other electronic devices through the first network 1898 (e.g., a short-range communication network such as Bluetooth, Wi-Fi Direct, or Infrared Data Association (IrDA)) or the second network 1899 (e.g., a long-range communication network such as a cellular network, the Internet, or a computer network (a LAN, a wide area network (WAN))). These various types of communication modules may be integrated into a single component (e.g., a single chip, etc.) or may be implemented as a plurality of separate components (e.g., a plurality of chips). The wireless communication module 1892 may identify and authenticate the electronic device 1801 within a communication network such as the first network 1898 and/or the second network 1899 by using subscriber information (e.g., an international mobile subscriber identifier (IMSI)) stored in the subscriber identification module 1896.

The antenna module 1897 may transmit or receive a signal and/or power to or from the outside (e.g., other electronic devices). An antenna may include a radiator made of a conductive pattern formed on a substrate (e.g., a printed circuit board (PCB)). The antenna module 1897 may include one or more antennas. When a plurality of antennas is included, the communication module 1890 may select an antenna suitable for a communication scheme used in a communication network such as the first network 1898 and/or the second network 1899, from among the plurality of antennas. A signal and/or power may be transmitted or received between the communication module 1890 and other electronic devices through the selected antenna. In addition to the antenna, other components (e.g., a radio-frequency integrated circuit (RFIC)) may be included as part of the antenna module 1897.

Some of the components may be connected to each other and exchange signals (e.g., commands, data) through a communication method between peripheral devices (e.g., a bus, a general-purpose input and output (GPIO), a serial peripheral interface (SPI), a mobile industry processor interface (MIPI)).

Commands or data may be transmitted or received between the electronic device 1801 and the external electronic device 1804 through the server 1808 connected to the second network 1899. The other electronic devices 1802 and 1804 may be of a type that is the same as or different from the electronic device 1801. All or some of the operations executed by the electronic device 1801 may be executed by one or more of the other electronic devices 1802, 1804, and 1808. For example, when the electronic device 1801 is required to perform a certain function or service, the electronic device 1801 may request one or more other electronic devices to perform some or all of the function or service instead of executing the function or service by itself. The one or more other electronic devices that have received the request may execute an additional function or service related to the request, and may transmit a result of the execution to the electronic device 1801. To this end, cloud computing, distributed computing, and/or client-server computing technologies may be used.

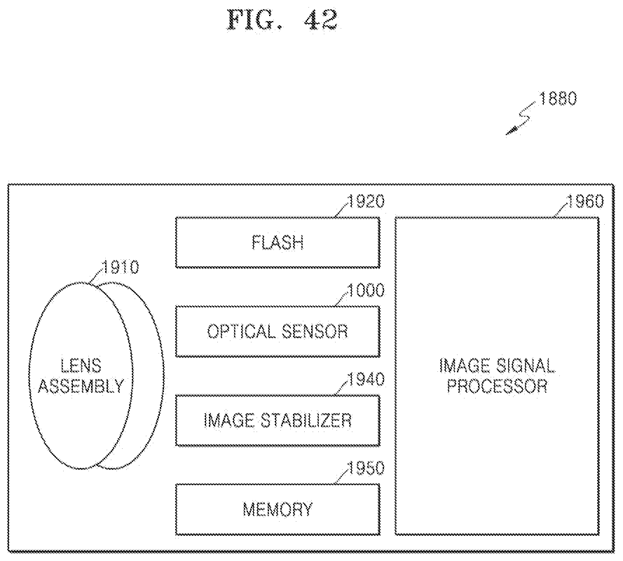

FIG. 42 is a block diagram schematically illustrating the camera module 1880 illustrated in FIG. 41.

Referring to FIG. 42, the camera module 1880 may include the lens assembly 1910, a flash 1920, the optical sensor 1000 (see FIG. 1), an image stabilizer 1940, a memory 1950 (e.g., a buffer memory), and/or the image signal processor 1960. The lens assembly 1910 may collect light emitted from an object to be image-captured. The camera module 1880 may include a plurality of lens assemblies 1910, and in this case, the camera module 1880 may be a dual camera, a 360-degree camera, or a spherical camera. Some of the plurality of lens assemblies 1910 may have the same lens attributes (e.g., an angle of view, a focal length, autofocus, F Number, optical zoom, etc.) or different lens attributes. The lens assembly 1910 may include a wide-angle lens or a telephoto lens.

The flash 1920 may emit light used to enhance light emitted or reflected from the object. The flash 1920 may include one or more light-emitting diodes (e.g., red-green-blue (RGB) LEDs, white LEDs, infrared LEDs, ultraviolet LEDs), and/or a xenon lamp. The optical sensor 1000 may be the optical sensor described above with reference to FIG. 1, and may obtain an image corresponding to an object by converting light emitted or reflected from the object and transmitted through the lens assembly 1910 into an electrical signal. The optical sensor 1000 may include one or more sensors selected from image sensors having different attributes, such as an RGB sensor, a black and white (BW) sensor, an IR sensor, or a UV sensor. Each of the sensors included in the optical sensor 1000 may be implemented as a CCD sensor and/or a CMOS sensor.

The image stabilizer 1940 may move one or more lenses included in the lens assembly 1910 or the optical sensor 1000 in a particular direction in response to movement of the camera module 1980 or the electronic device 1801 including the same, or may control an operating characteristic of the optical sensor 1000 (e.g., adjustment of read-out timing) such that a negative effect due to movement is compensated for. The image stabilizer 1940 may detect movement of the camera module 1880 or the electronic device 1801 by using a gyro sensor (not shown) or an acceleration sensor (not shown) arranged inside or outside the camera module 1880. The image stabilizer 1940 may be implemented optically.

In the memory 1950, some or all of the data obtained through the optical sensor 1000 may be stored for the next image processing operation. For example, when a plurality of images are obtained at high speed, the obtained original data (e.g., Bayer-patterned data, high-resolution data) may be stored in the memory 1950 and only a low-resolution image is displayed, and then the original data of a selected image (e.g., by a user selection) may be transmitted to the image signal processor 1960. The memory 1950 may be integrated into the memory 1830 of the electronic device 1801 or may be configured as a separate memory that operates independently.

The image signal processor 1960 may perform one or more image processes on an image obtained through the optical sensor 1000 or image data stored in the memory 1950. The one or more image processes may include depth map generation, three-dimensional modeling, panorama generation, feature point extraction, image synthesis, and/or image compensation (e.g., noise reduction, resolution adjustment, brightness adjustment, blurring, sharpening, softening). The image signal processor 1960 may perform control (e.g., exposure time control, or read-out timing control) of components (e.g., the optical sensor 1000) included in the camera module 1880. An image processed by the image signal processor 1960 may be stored again in the memory 1950 for further processing or may be provided to external components (e.g., the memory 1830, the display device 1860, the electronic device 1802, the electronic device 1804, the server 1808) of the camera module 1880. The image signal processor 1960 may be integrated into the processor 1820 or may be configured as a separate processor that operates independently of the processor 1820. When the image signal processor 1960 is configured as a processor separate from the processor 1820, an image processed by the image signal processor 1960 may be displayed through the display device 1860 after further image processing by the processor 1820.

The electronic device 1801 may include a plurality of camera modules 1880 having respective different attributes or functions. In this case, one of the plurality of camera modules 1880 may be a wide-angle camera, and the other may be a telephoto camera. Similarly, one of the plurality of camera modules 1880 may be a front camera, and the other may be a rear camera.

FIGS. 43 to 52 are diagrams illustrating various examples of electronic devices including optical sensors according to various embodiments.

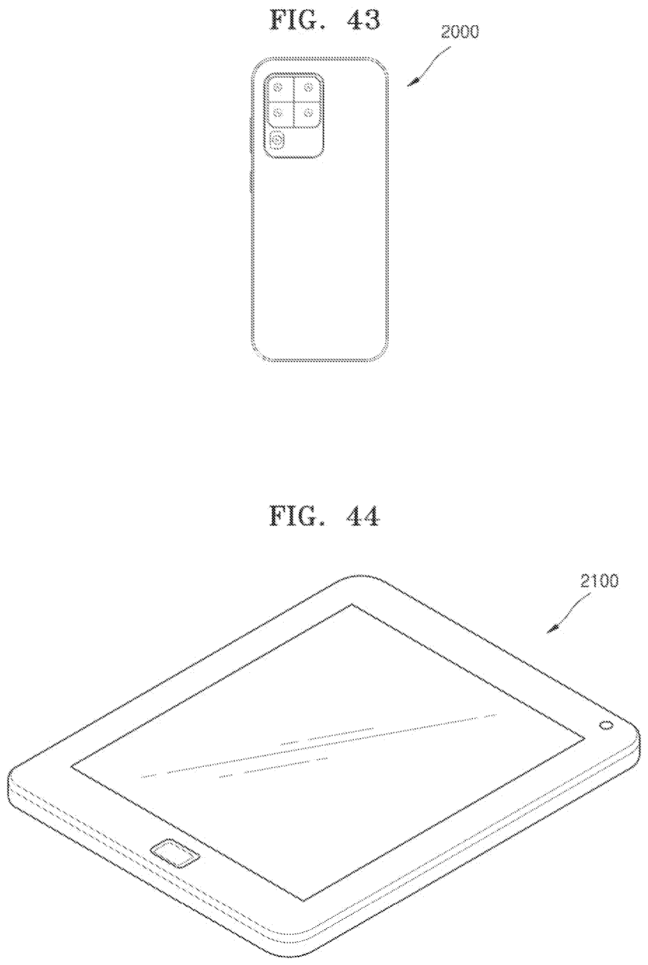

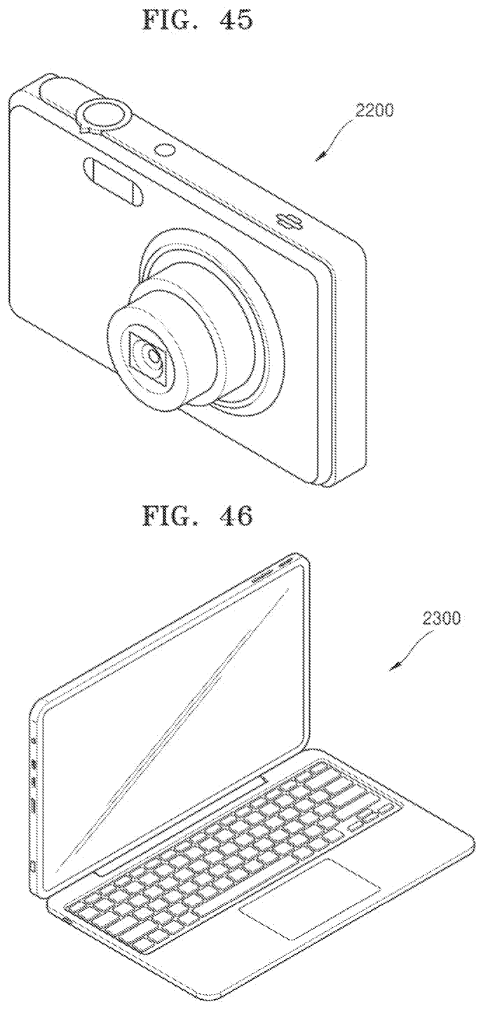

The optical sensor 1000 (see FIG. 1) according to various example embodiments may be applied to a mobile phone or smart phone 2000 illustrated in FIG. 43, a tablet or smart tablet 2100 illustrated in FIG. 44, a digital camera or camcorder 2200 illustrated in FIG. 45, a notebook computer 2300 illustrated in FIG. 46, or a television or smart television 2400 illustrated in FIG. 47. For example, the smart phone 2000 or the smart tablet 2100 may include a plurality of high-resolution cameras each equipped with a high-resolution optical sensor. Depth information of objects in an image may be extracted, out-focusing of an image may be adjusted, or objects in an image may be automatically identified, by using the high-resolution cameras.

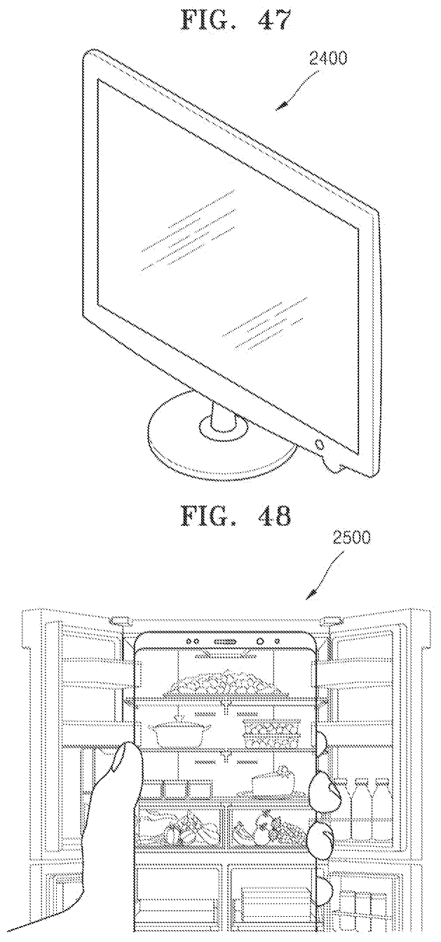

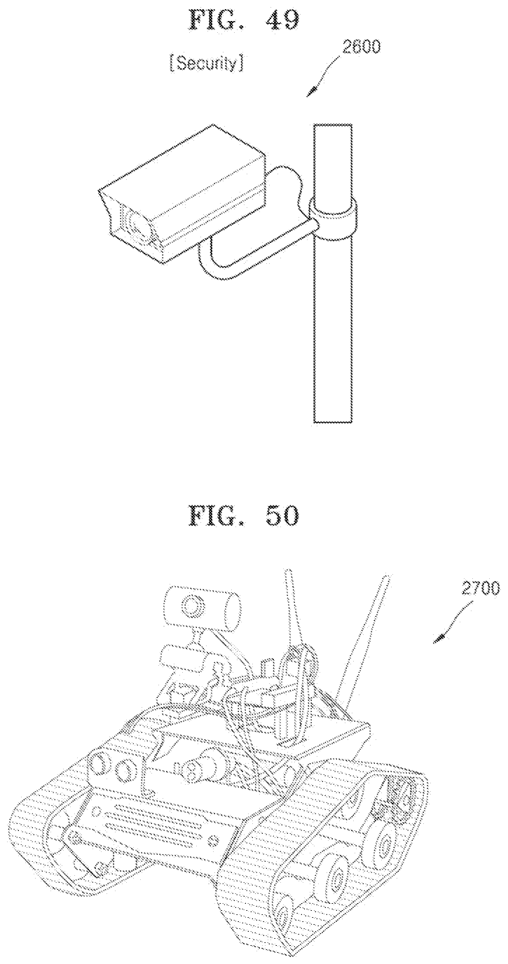

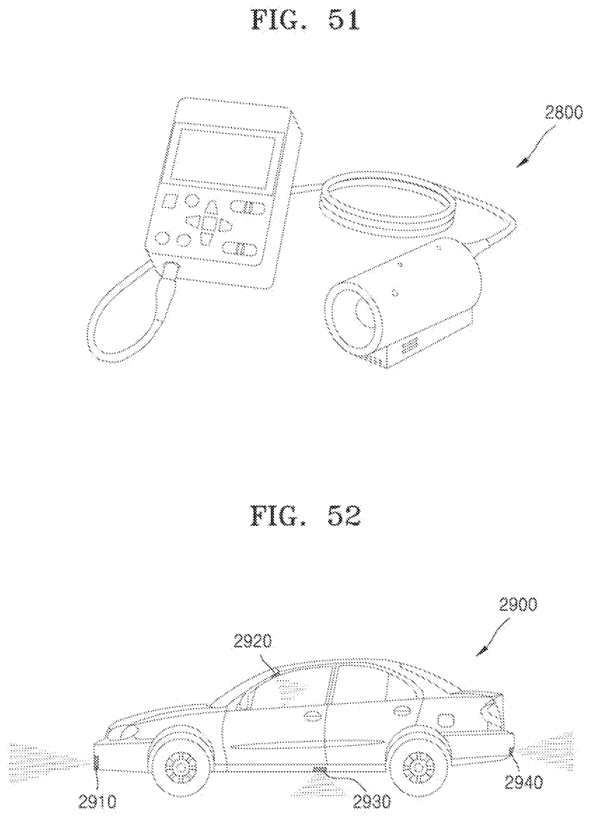

Also, the optical sensor 1000 may be applied to a smart refrigerator 2500 illustrated in FIG. 48, a security camera 2600 illustrated in FIG. 49, a robot 2700 illustrated in FIG. 50, a medical camera 2800 illustrated in FIG. 51. For example, the smart refrigerator 2500 may automatically recognize food in the refrigerator by using the optical sensor, and inform a user of the presence or absence of particular food, the type of food being stored or released, and the like, through a smart phone. The security camera 2600 may provide an ultra-high resolution image and may recognize an object or a person in an image even in a dark environment, by using high sensitivity. The robot 2700 may be deployed in a disaster or industrial site which cannot be directly accessed by a human, and provide a high-resolution image. The medical camera 2800 may provide a high-resolution image for diagnosis or surgery, and may dynamically adjust its field of view.

Also, the optical sensor 1000 may be applied to a vehicle 2900 as illustrated in FIG. 52. The vehicle 2900 may include a plurality of vehicle cameras 2910, 2920, 2930, and 2940 arranged at various positions. Each of the vehicle cameras 2910, 2920, 2930, and 2940 may include an optical sensor according to an example embodiment. The vehicle 2900 may provide various pieces of information about the inside or the surroundings of the vehicle 2900 to a driver by using the plurality of vehicle cameras 2910, 2920, 2930, and 2940, and may provide information required for autonomous driving by automatically recognizing an object or a person in an image.

According to various example embodiments, provided are an optical sensor including a nanophotonic microlens array having a structure configured to reduce the amount of incident light collected on the center of a DTI structure included in each of a plurality of pixels of a sensor substrate while implementing an autofocusing (AF) technique, and an electronic device including the optical sensor.

According to various example embodiments, an AF technique may be implemented by using a single nanophotonic microlens in which a plurality of convex lenses overlap each other, and the amount of incident light collected at the center of a DTI structure included in each of the plurality of pixels of the sensor substrate may be reduced.

According to various example embodiments, provided are an optical sensor including a nanophotonic microlens array configured to change a traveling direction of incident light, which is incident on an edge of the optical sensor at a high CRA to improve the sensitivity of a sensor substrate including a plurality of pixels, and an electronic device including the optical sensor.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims, and their equivalents.

What is claimed is:

1. An optical sensor comprising:
a sensor substrate comprising a plurality of pixels configured to sense incident light;
a filter layer provided on the sensor substrate and comprising a plurality of filters respectively corresponding to the plurality of pixels, the plurality of filters being configured to transmit light of a certain wavelength band; and
a nanophotonic microlens array provided on the filter layer and comprising a plurality of nanophotonic microlenses, each of the plurality of nanophotonic microlenses being configured to focus incident light on a corresponding pixel among the plurality of pixels,
wherein each of the plurality of pixels comprises a deep trench isolation (DTI) and a plurality of photosensitive cells that are electrically separated from each other by the DTI structure and are two-dimensionally arranged in a first direction and a second direction perpendicular to the first direction, each of the plurality of photosensitive cells being configured to independently sense light,
wherein each of the plurality of nanophotonic microlenses is formed such that light transmitted through each nanophotonic microlens has a phase profile having a plurality of convex regions and is formed to collect incident light on each of a plurality of regions, which are spaced apart from centers of the plurality of photosensitive cells included in the corresponding pixel, toward the DTI structure, and
wherein a portion of incident light transmitted through each of the plurality of nanophotonic microlenses is incident on the DTI structure.

2. The optical sensor of claim 1, wherein each of the plurality of nanophotonic microlenses is formed such that a number of convex regions of the phase profile of the light transmitted through each of the plurality of nanophotonic microlenses is equal to a number of photosensitive cells included in the pixel corresponding to each of the plurality of nanophotonic microlenses.

3. The optical sensor of claim 1, wherein each of the plurality of nanophotonic microlenses is formed such that light transmitted through a first region corresponding to the DTI structure of each of the plurality of nanophotonic microlenses has a phase profile of a region in which the plurality of convex regions overlap each other, and light transmitted through a second region that is a remaining region other than the first region in each of the plurality of nanophotonic microlenses has a phase profile having the plurality of convex regions.

4. The optical sensor of claim 1, wherein each of the plurality of nanophotonic microlenses is formed such that the plurality of convex regions of the phase profile of the light transmitted through each of the plurality of nanophotonic microlenses are symmetrically distributed with respect to a first area corresponding to the DTI structure of each of the plurality of nanophotonic microlenses.

5. The optical sensor of claim 1, wherein each of the plurality of nanophotonic microlenses is formed such that a phase profile of light transmitted through a third region corresponding to a region between the DTI structure and center points of the plurality of photosensitive cells of each of the plurality of nanophotonic microlenses comprises a plurality of maximum points.

6. The optical sensor of claim 1, wherein each of a plurality of first nanophotonic microlenses, which is provided in a central region of the nanophotonic microlens array, is formed such that a plurality of convex regions of a phase profile of light transmitted through each of the plurality of first nanophotonic microlenses are symmetrically provided with respect to a first region corresponding to a DTI structure of each of the plurality of first nanophotonic microlenses, and
wherein each of a plurality of second nanophotonic microlenses, which is provided in a peripheral region of the nanophotonic microlens array, is formed such that a phase profile of light transmitted through each of the plurality of second nanophotonic microlenses has an inclined linear phase profile and a convex phase profile mixed with each other.

7. The optical sensor of claim 6, wherein the nanophotonic microlens array comprises a plurality of third nanophotonic microlenses provided farther from a central region of the nanophotonic microlens array than the plurality of second nanophotonic microlenses, and
wherein each of the plurality of second nanophotonic microlenses is formed such that a first slope of the linear phase profile of the light transmitted through each of the plurality of second nanophotonic microlenses is less than a second slope of the linear phase profile of light transmitted through each of the plurality of third nanophotonic microlenses.

8. The optical sensor of claim 1, wherein each of the plurality of nanophotonic microlenses comprises a convex lens structure having a plurality of convex portions.

9. The optical sensor of claim 8, wherein a number of convex portions included in each of the plurality of nanophotonic microlenses is equal to a number of photosensitive cells included in each pixel corresponding to each of the plurality of nanophotonic microlenses.

10. The optical sensor of claim 8, wherein a first region corresponding to the DTI structure of each of the plurality of nanophotonic microlenses is concave, and the plurality of convex portions are provided in a second region that is a remaining region other than the first region of each of the plurality of nanophotonic microlenses, and
wherein the plurality of convex portions of each of the plurality of nanophotonic microlenses are symmetrically provided with respect to a first region corresponding to the DTI structure of each of the plurality of nanophotonic microlenses.

11. The optical sensor of claim 8, wherein each of the plurality of nanophotonic microlenses is formed such that maximum points of the plurality of convex portions are provided in a third region corresponding to a region between the DTI structure and center points of the plurality of photosensitive cells of each of the plurality of nanophotonic microlenses.

12. The optical sensor of claim 1, wherein each of the plurality of nanophotonic microlenses comprises a single convex lens structure in which a plurality of convex lens-shaped portions partially overlap each other with respect to a center point of the nanophotonic microlens, and
wherein a number of the plurality of convex lens-shaped portions corresponds to a number of photosensitive cells included in the pixel corresponding to the nanophotonic microlens.

13. The optical sensor of claim 8, wherein each of a plurality of first nanophotonic microlenses, which is provided in a central region of the nanophotonic microlens array, is formed such that a plurality of first convex portions of each of the plurality of first nanophotonic microlenses are symmetrically provided with respect a first region corresponding to the DTI structure of each of the plurality of first nanophotonic microlenses,
wherein each of a plurality of 2-1st nanophotonic microlenses, which is provided in a left peripheral region of the nanophotonic microlens array, is formed such that each of maximum points of a plurality of 2-1st convex portions of each of the plurality of 2-1st nanophotonic microlenses are respectively spaced apart from each of center points of the plurality of photosensitive cells in the first direction, and provided to be closer to a center line of the DTI structure in the first direction than to each of the center points of the plurality of photosensitive cells,
wherein each of a plurality of 2-2nd nanophotonic microlenses, which is provided in a right peripheral region of the nanophotonic microlens array, is formed such that each of maximum points of a plurality of 2-2nd convex portions of each of the plurality of 2-2nd nanophotonic microlenses are respectively spaced apart from each of the center points of the plurality of photosensitive cells in a direction opposite to the first direction, and are provided to be closer to the center line of the DTI structure in the first direction than to each of the center points of the plurality of photosensitive cells, and
wherein the plurality of 2-1st convex portions of each of the plurality of 2-1st nanophotonic microlenses and the plurality of 2-2nd convex portions of each of the plurality of 2-2nd nanophotonic microlenses are symmetrically provided in the second direction with respect to the center line of the DTI structure in the first direction.

14. The optical sensor of claim 13, wherein the nanophotonic microlens array comprises a plurality of third nanophotonic microlenses provided farther from a central region of an array of the nanophotonic microlenses than the plurality of 2-1st nanophotonic microlenses and the plurality of 2-2nd nanophotonic microlenses, and
wherein a distance by which a plurality of maximum points of a plurality of third convex portions of each of the plurality of third nanophotonic microlenses are spaced apart from the center points of the plurality of photosensitive cells is greater than a distance by which a plurality of maximum points of a plurality of second convex portions of each of the plurality of 2-1st nanophotonic microlenses and the plurality of 2-2nd nanophotonic microlenses are spaced apart from the plurality of center points of the plurality of photosensitive cells.

15. The optical sensor of claim 1, wherein the plurality of pixels comprise a plurality of first pixels each comprising a plurality of first photosensitive cells configured to sense light of a first wavelength band and a plurality of second pixels each comprising a plurality of second photosensitive cells configured to sense light of a second wavelength band that is shorter than the first wavelength band,
wherein the filter layer comprises a plurality of first filters respectively corresponding to the plurality of first pixels and configured to transmit light of the first wavelength band, and a plurality of second filters respectively corresponding to the plurality of second pixels and configured to transmit light of the second wavelength band, and
wherein the nanophotonic microlens array comprises:
a plurality of first nanophotonic microlenses corresponding to the plurality of first filters, respectively, and configured to focus light on the plurality of first pixels, and
a plurality of second nanophotonic microlenses corresponding to the plurality of second filters, respectively, and configured to focus light on the plurality of second pixels.

16. The optical sensor of claim 15, wherein the plurality of first nanophotonic microlenses and the plurality of second nanophotonic microlenses are formed such that a plurality of second convex regions included in a phase profile of light transmitted through each of the plurality of second nanophotonic microlenses are more convex than a plurality of first convex regions included in a phase profile of light transmitted through each of the plurality of first nanophotonic microlenses.

17. The optical sensor of claim 15, wherein each of the plurality of first nanophotonic microlenses comprises a first convex lens structure having a plurality of first convex portions, each of the plurality of second nanophotonic microlenses comprises a second convex lens structure having a plurality of second convex portions, and
wherein the plurality of second convex portions are formed to be more convex than the plurality of first convex portions.

18. The optical sensor of claim 17, wherein a number of first convex portions included in each of the plurality of first nanophotonic microlenses is equal to a number of first photosensitive cells included in each of the plurality of first pixels, and a number of second convex portions included in each of the plurality of second nanophotonic microlenses is equal to a number of second photosensitive cells included in each of the plurality of second pixels,
wherein each of the plurality of first nanophotonic microlenses is formed such that the plurality of first convex portions included in the first nanophotonic microlens are symmetrically provided with respect a first region corresponding to the DTI structure of the first nanophotonic microlens, and
wherein each of the plurality of second nanophotonic microlenses is formed such that the plurality of second convex portions included in the second nanophotonic microlens are symmetrically provided with respect a second region corresponding to the DTI structure of the second nanophotonic microlens.

19. The optical sensor of claim 17, wherein each of the plurality of first nanophotonic microlenses and each of the plurality of second nanophotonic microlenses provided in a central region of the nanophotonic microlens array are formed such that the plurality of first convex portions of each of the plurality of first nanophotonic microlenses are symmetrically provided with respect to a first region corresponding to the DTI structure of each of the plurality of first nanophotonic microlenses, and the plurality of second convex portions of each of the plurality of second nanophotonic microlenses are symmetrically provided with respect to a second region corresponding to the DTI structure of each of the plurality of second nanophotonic microlenses,
wherein each of the plurality of first nanophotonic microlenses and each of the plurality of second nanophotonic microlenses provided in a left peripheral region of the nanophotonic microlens array are formed such that maximum points of the plurality of first convex portions of each of the plurality of first nanophotonic microlenses and maximum points of the plurality of second convex portions of each of the plurality of second nanophotonic microlenses are respectively spaced apart from each of center points of the plurality of first photosensitive cells included in each of the plurality of first pixels and each of center points of the plurality of second photosensitive cells included in each of the plurality of second pixels in the first direction, and are provided to be closer to a center line of the DTI structure in the first direction than to each of center points of the plurality of first photosensitive cells and each of center points of the plurality of second photosensitive cells, and
wherein each of the plurality of first nanophotonic microlenses and each of the plurality of second nanophotonic microlenses provided in a right peripheral region of the nanophotonic microlens array are formed such that maximum points of the plurality of first convex portions of each of the plurality of first nanophotonic microlenses and maximum points of the plurality of second convex portions of each of the plurality of second nanophotonic microlenses are respectively spaced apart from each of center points of the plurality of first photosensitive cells included in each of the plurality of first pixels and each of center points of the plurality of second photosensitive cells included in each of the plurality of second pixels in a direction opposite to the first direction, and are provided to be closer to a center line of the DTI structure in the first direction than to each of center points of the plurality of first photosensitive cells and each of center points of the plurality of second photosensitive cells.

20. The optical sensor of claim 19, wherein the plurality of first convex portions of each of the plurality of first nanophotonic microlenses provided in the left peripheral region and the right peripheral region of the nanophotonic microlens array and the plurality of second convex portions of each of the plurality of second nanophotonic microlenses provided in the left peripheral region and the right peripheral region of the nanophotonic microlens array are symmetrically provided in the second direction with respect to a center line of the DTI structure.
